(19) United States
(12) Patent Application Publication
(10) Pub. No.: US 2024/0389299 A1
(43) Pub. Date: Nov. 21, 2024

(54) DYNAMIC RANDOM ACCESS MEMORY DEVICES WITH ENHANCED DATA RETENTION AND METHODS OF FORMING THE SAME

(71) Applicant: Taiwan Semiconductor Manufacturing Company Limited, Hsinchu (TW)

(72) Inventors: Hung-Li CHIANG, Taipei City (TW); Jer-Fu WANG, Taipei City (TW); Tzu-Chiang CHEN, Hsinchu City (TW); Jui-Jen WU, Hsinchu (TW); Meng-Fan CHANG, Taichung City (TW)

(21) Appl. No.: 18/788,543

(22) Filed: Jul. 30, 2024

Related U.S. Application Data
(62) Division of application No. 17/693,534, filed on Mar. 14, 2022.
(60) Provisional application No. 63/281,329, filed on Nov. 19, 2021.

(51) Int. Cl. H10B 12/00; G11C 5/06

(52) U.S. Cl. CPC H10B 12/31; G11C 5/063; H10B 12/0335; H10B 12/056; H10B 12/09; H10B 12/36; H10B 12/50; H10B 12/482; H10B 12/485; H10B 12/488

(57) ABSTRACT

A memory cell includes a write access transistor, a storage transistor, and a read access transistor. A gate of the write access transistor is connected to a write word line, a source of the write access transistor is connected to a write bit line, and a drain of the write access transistor is connected to a gate of the storage transistor. A source of the storage transistor is connected to a source line and a drain of the storage transistor is connected to a source of the read access transistor. A gate of the read access transistor is connected to a read bit line and a drain of the read access transistor is connected to read bit line. The memory cell further includes a capacitive element having a first connection to the gate of the storage transistor and a second connection to a reference voltage source.

### RELATED APPLICATION

This application is a divisional application of U.S. patent application Ser. No. 17/693,534 entitled “Dynamic Random Access Memory Devices with Enhanced Retention and Methods of Forming the Same” filed on Mar. 14, 2022 which claims priority to U.S. Provisional Patent Application No. 63/281,329 entitled “DRAM with Enhanced Data Retention” filed on Nov. 19, 2021, the entire contents of both of which are hereby incorporated by reference for all purposes.

### BACKGROUND

The semiconductor industry has grown due to continuous improvements in integration density of various electronic components (e.g., transistors, diodes, resistors, inductors, capacitors, etc.). For the most part, these improvements in integration density have come from successive reductions in minimum feature size, which allow more components to be integrated into a given area. In this regard, individual transistors, interconnects, and related structures have become increasingly smaller and there is an ongoing need to develop new materials, processes, and designs of semiconductor devices and interconnects to allow further progress.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of an example semiconductor structure after formation of complementary metal-oxide-semiconductor (CMOS) transistors, first metal interconnect structures formed in lower-level dielectric material layers, and an isolation dielectric layer, according to various embodiments.

FIG. 2 is a schematic illustration of a portion of a memory array, according to various embodiments.

FIG. 3 is a schematic illustration of a memory cell having a capacitive element, according to various embodiments.

FIG. 4A is a top view of a memory cell having a capacitive element, according to various embodiments.

FIG. 4B is a vertical cross-sectional view of the memory cell of FIG. 4A defined by the cross section B-B′ shown in FIG. 4A, according to various embodiments.

FIG. 4C is a further vertical cross-sectional view of the memory cell of FIG. 4A defined by the cross section C-C′ shown in FIG. 4A, according to various embodiments.

FIG. 4D is a further vertical cross-sectional view of the memory cell of FIG. 4A defined by the cross section D-D′ shown in FIG. 4A, according to various embodiments.

FIG. 4E is a further vertical cross-sectional view of the memory cell of FIG. 4A defined by the cross section E-E′ shown in FIG. 4A, according to various embodiments.

FIG. 4F is a further vertical cross-sectional view of the memory cell of FIG. 4A defined by the cross section F-F′ shown in FIG. 4A, according to various embodiments.

FIG. 5A is a top view of a further memory cell having a capacitive element, according to various embodiments.

FIG. 5B is a vertical cross-sectional view of the memory cell of FIG. 5A defined by the cross section B-B′ shown in FIG. 5A, according to various embodiments.

FIG. 6A is a top view of a further memory cell having a capacitive element, according to various embodiments.

FIG. 6B is a vertical cross-sectional view of the memory cell of FIG. 6A defined by the cross section B-B′ shown in FIG. 6A, according to various embodiments.

FIG. 7A is a vertical cross-sectional view of an intermediate structure that may be used in the formation of a memory cell, according to various embodiments.

FIG. 7B is a vertical cross-sectional view of a further intermediate structure that may be used in the formation of a memory cell, according to various embodiments.

FIG. 7C is a vertical cross-sectional view of a further intermediate structure that may be used in the formation of a memory cell, according to various embodiments.

FIG. 7D is a vertical cross-sectional view of a further intermediate structure that may be used in the formation of a memory cell, according to various embodiments.

FIG. 7E is a vertical cross-sectional view of a further intermediate structure that may be used in the formation of a memory cell, according to various embodiments.

FIG. 7F is an enlarged vertical cross-sectional view of a portion of the intermediate structure of FIG. 7E, according to various embodiments.

FIG. 7G is a vertical cross-sectional view of a further intermediate structure that may be used in the formation of a memory cell, according to various embodiments.

FIG. 7H is a vertical cross-sectional view of a further intermediate structure that may be used in the formation of a memory cell, according to various embodiments.

FIG. 7I is a vertical cross-sectional view of a further intermediate structure that may be used in the formation of a memory cell, according to various embodiments.

FIG. 7J is a vertical cross-sectional view of a further intermediate structure that may be used in the formation of a memory cell, according to various embodiments.

FIG. 8 is a three-dimensional view of a memory cell, according to various embodiments.

FIG. 9A is a schematic illustration of a memory cell having a first configuration of a write access transistor, a storage transistor, an a read access transistor, according to various embodiments.

FIG. 9B is a schematic illustration of a memory cell having a further configuration of a write access transistor, a storage transistor, an a read access transistor, according to various embodiments.

FIG. 9C is a schematic illustration of a memory cell having a further configuration of a write access transistor, a storage transistor, an a read access transistor, according to various embodiments.

FIG. 10 is a schematic illustration of a portion of a memory array having a high-density configuration, according to various embodiments.

FIG. 11 is a flowchart illustrating a method of fabricating a memory cell, according to various embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

According to various embodiments of this disclosure, a memory cell is provided that may be formed in a front-end-of-line (FEOL) process or in a back-end-of-line (BEOL) process. In embodiments in which the memory cell may be formed in a BEOL process, the memory cell may be incorporated with other BEOL circuit components such as thin film transistor (TFT) devices. As such, the disclosed memory cell may include materials that may be processed at low temperatures and thus, may not damage previously fabricated devices (e.g., FEOL and MEOL devices). The memory cell may include three transistors for write and non-destructive read operations. Such memory cells that include three transistors typically implement a layout that is asymmetric and as a result includes wasted foot print space. Also, the retention time of such memory cells is short due to the parasitic capacitance of storage MOS is small. Thus, embodiment memory cells may further include a capacitive element that may reduce leakage currents, power dissipation, and a memory refresh rate. Further, the capacitive element may be provided without increasing an area occupied by the three transistors. Various embodiment memory cells disclosed herein may therefore be incorporated with only minor modification of existing array designs.

Embodiment memory cells may include a write access transistor (MW), a storage transistor (MS), and a read access transistor (MR). A gate of the write access transistor may be connected to a write word line, a source of the write access transistor may be connected to a write bit line, and a drain of the write access transistor may be connected to a gate of the storage transistor. A source of the storage transistor may be connected to a source line and a drain of the storage transistor may be connected to a source of the read access transistor. A gate of the read access transistor may be connected to a read word line and a drain of the read access transistor may be connected to read bit line. The memory cell further may include a capacitive element having a first connection to the gate of the storage transistor (as well as to the drain of the write access transistor) and a second connection to a reference voltage source.

According to various embodiments disclosed herein, a memory cell is provided that may include a read bit line and a read word line; a write bit line and a write word line; a source line; a write access transistor (MW) including first source, a first drain, and a first gate; a storage transistor (MS) including a second source, a second drain, and a second gate; and a read access transistor (MR) including a third source, a third drain, and a third gate. The first gate may be electrically connected to the write word line and the first source may be electrically connected to the write bit line; the second gate may be electrically connected to the first drain and the second source may be electrically connected to the source line; the third source may be electrically connected to the second drain; the third gate may be electrically connected to the read word line and the third drain may be electrically connected to the read bit line. The memory cell may further include a capacitive element having a first terminal and a second terminal, such that the first terminal may be electrically connected to the first drain and the second gate. The second terminal may be electrically connected to a reference voltage source.

In a further embodiment, a memory cell may include a first oxide definition region formed on a substrate; a second oxide definition region formed on the substrate; a first continuous polysilicon region formed over the first oxide definition region; a second continuous polysilicon region formed over the first oxide definition region and the second oxide definition region; a third continuous polysilicon region formed over the second oxide definition region; and a capacitive element formed on one of the first oxide definition region, the second oxide definition region, or the second continuous polysilicon region. A first portion of the first continuous polysilicon region may be configured to be overlapping with the first oxide definition region to thereby form a first gate of a write access transistor, a second portion of the second continuous polysilicon region may be configured to be overlapping with the second oxide definition region to thereby form a gate of a storage transistor, and a third portion of the third continuous polysilicon region maty be configured to be overlapping with the second oxide definition region to thereby form a third gate of a read access transistor.

An embodiment method of fabricating a memory cell may include forming a first oxide definition region on a substrate; forming a second oxide definition region on the substrate; forming a first continuous polysilicon region over the first oxide definition region; forming a second continuous polysilicon region over and electrically connected to the first oxide definition region, and overlapping the second oxide definition region; forming a third continuous polysilicon region over the second oxide definition region; and forming a capacitive element on the first oxide definition region, on the second oxide definition region, or on the second continuous polysilicon region. Forming the first continuous polysilicon region further may include configuring a first portion first continuous polysilicon region to overlap with the first oxide definition region to thereby form a first gate of a write access transistor. Forming the second continuous polysilicon region may include configuring a second portion of the second continuous polysilicon region to overlap with the second oxide definition region to thereby form a second gate of a storage transistor, and forming the third continuous polysilicon region may further include configuring a third portion of the third continuous polysilicon region to overlap with the second oxide definition region to thereby form a third gate of a read access transistor.

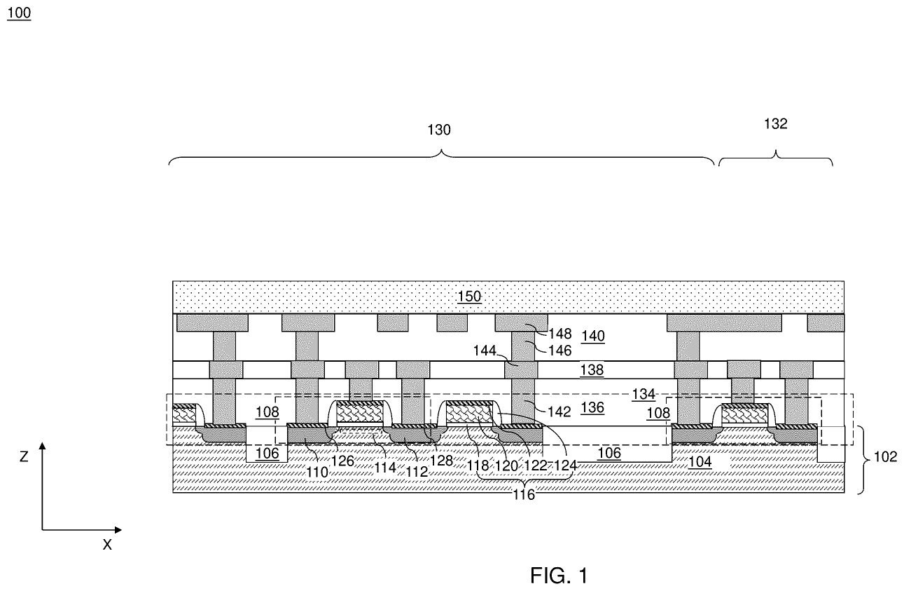

FIG. 1 illustrates a semiconductor structure 100, according to various embodiments. The semiconductor structure 100 may include a substrate 102, which may be a semiconductor substrate such as a commercially available silicon substrate. The substrate 102 may include a semiconductor material layer 104 or at least at an upper portion thereof. The semiconductor material layer 104 may be a surface portion of a bulk semiconductor substrate, or may be a top semiconductor layer of a semiconductor-on-insulator (SOI) substrate. In one embodiment, the semiconductor material layer 104 may include a single crystalline semiconductor material such as single crystalline silicon. In one embodiment, the substrate 102 may include a single crystalline silicon substrate including a single crystalline silicon material.

Shallow trench isolation structures 106 including a dielectric material such as silicon oxide may be formed in an upper portion of the semiconductor material layer 104. Suitably doped semiconductor wells, such as p-type wells and n-type wells, may be formed within each area that is laterally enclosed by a portion of the shallow trench isolation structures 106. Field effect transistors 108 may be formed over a top surface of the semiconductor material layer 104. For example, each of the field effect transistors 108 may include a source electrode 110, a drain electrode 112, a semiconductor channel 114 that may include a surface portion of the substrate 102 extending between the source electrode 110 and the drain electrode 112, and a gate structure 116. The semiconductor channel 114 may include a single crystalline semiconductor material.

Each gate structure 116 may include a gate dielectric layer 118, a gate electrode 120, a gate polycide layer 122, and a dielectric gate spacer 124. A source-side metal-semiconductor alloy region 126 may be formed on each source electrode 110, and a drain-side metal-semiconductor alloy region 128 may be formed on each drain electrode 112. The gate electrode 120 may be formed as a region of heavily doped polysilicon that may have a minimum resistivity of approximately 300 μohm-cm. The resistivity of the gate electrode 120 may be reduced by the formation of the polycide layer 122. Similarly, the resistivity of the doped (p-type or n-type) wells may be reduced by the formation of the source-side metal-semiconductor alloy region 126 and the drain-side metal-semiconductor alloy region 128.

A wide variety of noble and refractory metals may form compounds with silicon (i.e., silicides) and with polysilicon (i.e., polycides) that have reduced specific resistivities. Such silicides/polycides may include CoSi₂ (18-25 μohm-cm), HfSi₂ (45-50 μohm-cm), MoSi₂ (100 μohm-cm), NiSi₂ (50-60 μohm-cm), Pd₂Si (30-50 μohm-cm), PtSi (28-35 μohm-cm), TaSi₂ (35-55 μohm-cm), TiSi₂ (13-25 μohm-cm), WSi₂ (70 μohm-cm), and ZrSi₂ (35-40 μohm-cm). Other suitable metal-semiconductor compounds within the contemplated scope of disclosure may also be used. The sheet resistance of the gate electrode 120, the source electrode 110, and the drain electrode 112 may be reduced by forming a low-resistivity, shunting silicide/polycide layer (i.e., the gate polycide layer 122, the source-side metal-semiconductor alloy region 126, and the drain-side metal-semiconductor alloy region 128, respectively) on each of their surfaces.

According to an embodiment, the gate polycide layer 122, the source-side metal-semiconductor alloy region 126, and the drain-side metal-semiconductor alloy region 128 may be formed in single “self-aligned silicides” (i.e., “salicide”) process. In this regard, after formation of the gate electrode 120 and the doped wells, an oxide may be formed (e.g., by CVD deposition) over the structure and etched (e.g., using a reactive ion etch) to form the dielectric gate spacer 124. In this regard, oxide formed along edges of the gate may be thicker than oxide formed over other regions so that, during an etching process, some oxide may remain on the sides of the gate at the point when the oxide is completely removed from the source electrode 110, the drain electrode 112, and on a top surface of the gate electrode 120. The oxide remaining on the sides of the gate electrode 120 may form the dielectric gate spacer 124. The dielectric gate spacer 124 may be used to prevent silicide/polycide formation on the side of the gate electrode 120 to prevent formation of short-circuit connections between the gate electrode 120 and the source electrode 110 and/or the drain electrode 112.

Metal may be deposited over the structure and a sintering process may be performed to thereby form silicides in regions where the metal touches silicon or polysilicon. Unreacted metal may then be removed with a selective etch that does not attack the silicides/polycides. The resulting silicide/polycide materials may thereby be automatically self-aligned to the gate electrode 120, to the source electrode 110, and to the drain electrode 112. In other words, the gate polycide layer 122 may be aligned with the gate electrode 120, the source-side metal-semiconductor alloy region 126 may be aligned with the source electrode 110, and the drain-side metal-semiconductor alloy region 128 may be aligned with the drain electrode 112.

The devices formed on the top surface of the semiconductor material layer 104 may include complementary metal-oxide-semiconductor (CMOS) transistors and optionally additional semiconductor devices (such as resistors, diodes, capacitors, etc.), and are collectively referred to as CMOS circuitry 134. The semiconductor structure 100 of FIG. 1 may include a memory array region 130 in which an array of memory cells may be subsequently formed. The first exemplary structure may further include a peripheral region 132 in which metal wiring for the array of memory devices is provided. Generally, the field effect transistors 108 in the CMOS circuitry 134 may be electrically connected to an electrode of a respective memory cell by a respective set of metal interconnect structures.

Devices (such as field effect transistors 108) in the peripheral region 132 may provide functions that operate the array of memory cells to be subsequently formed. Specifically, devices in the peripheral region may be configured to control the programming operation, the erase operation, and the sensing (read) operation of the array of memory cells. For example, the devices in the peripheral region may include a sensing circuitry and/or a programming circuitry.

One or more of the field effect transistors 108 in the CMOS circuitry 134 may include a semiconductor channel 114 that contains a portion of the semiconductor material layer 104 in the substrate 102. In embodiments in which the semiconductor material layer 104 may include a single crystalline semiconductor material such as single crystalline silicon, the semiconductor channel 114 of each of the field effect transistors 108 in the CMOS circuitry 134 may include a single crystalline semiconductor channel such as a single crystalline silicon channel. In one embodiment, a plurality of field effect transistors 108 in the CMOS circuitry 134 may include a respective node that is subsequently electrically connected to a node of a respective memory cell to be subsequently formed. For example, a plurality of field effect transistors 108 in the CMOS circuitry 134 may include a respective source electrode 110 or a respective drain electrode 112 that is subsequently electrically connected to a node of a respective memory cell to be subsequently formed.

A memory array may be formed as a collection of the field effect transistors 108 in the CMOS circuitry 134 in a FEOL process. Alternatively, a memory array may be formed as a collection of transistors (e.g., thin film transistors including ferroelectric memory cells) to be subsequently formed in an insulating matrix layer 150 in a BEOL process. In one embodiment, the CMOS circuitry 134 may include a programming control circuit configured to control gate voltages of a set of field effect transistors 108 that may be used for programming a respective memory cell and to control gate voltages of transistors (e.g., thin-film transistors) to be subsequently formed.

For example, in a ferroelectric memory array formed over the insulating matrix layer 150, the programming control circuit may be configured to provide a first programming pulse that programs a respective ferroelectric dielectric material layer in a selected ferroelectric memory cell into a first polarization state in which electrical polarization in the ferroelectric dielectric material layer points toward a first electrode of the selected ferroelectric memory cell, and to provide a second programming pulse that programs the ferroelectric dielectric material layer in the selected ferroelectric memory cell into a second polarization state in which the electrical polarization in the ferroelectric dielectric material layer points toward a second electrode of the selected ferroelectric memory cell.

In one embodiment, the substrate 102 may include a single crystalline silicon substrate, and the field effect transistors 108 may include a respective portion of the single crystalline silicon substrate as a semiconducting channel. As used herein, a “semiconducting” element refers to an element having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant.

According to an embodiment, the field effect transistors 108 may be subsequently electrically connected to drain electrodes and gate electrodes of access transistors including semiconducting metal oxide plates to be formed above the field effect transistors 108. In one embodiment, a subset of the field effect transistors 108 may be subsequently electrically connected to at least one of the drain electrodes and the gate electrodes. For example, the field effect transistors 108 may include first word line drivers configured to apply a first gate voltage to first word lines through a first subset of lower-level metal interconnect structures to be subsequently formed, and second word line drivers configured to apply a second gate voltage to second word lines through a second subset of the lower-level metal interconnect structures. Further, the field effect transistors 108 may include bit line drivers configured to apply a bit line bias voltage to bit lines to be subsequently formed, and sense amplifiers configured to detect electrical current that flows through the bit lines during a read operation.

Various metal interconnect structures formed within dielectric material layers may be subsequently formed over the substrate 102 and the semiconductor devices thereupon (such as field effect transistors 108). In an illustrative example, the dielectric material layers may include, for example, a first dielectric material layer 136 that may be a layer that surrounds the contact structure connected to the source and drains (sometimes referred to as a contact-level dielectric material layer), a first interconnect-level dielectric material layer 138, and a second interconnect-level dielectric material layer 140. The metal interconnect structures may include device contact via structures 142 formed in the first dielectric material layer 136 and contact a respective component of the CMOS circuitry 134, first metal line structures 144 formed in the first interconnect-level dielectric material layer 138, first metal via structures 146 formed in a lower portion of the second interconnect-level dielectric material layer 140, and second metal line structures 148 formed in an upper portion of the second interconnect-level dielectric material layer 140.

Each of the dielectric material layers (136, 138, 140) may include a dielectric material such as undoped silicate glass, a doped silicate glass, organosilicate glass, amorphous fluorinated carbon, porous variants thereof, or combinations thereof. Each of the metal interconnect structures (142, 144, 146, 148) may include at least one conductive material, which may be a combination of a metallic liner (such as a metallic nitride or a metallic carbide) and a metallic fill material. Each metallic liner may include TiN, TaN, WN, TiC, TaC, and WC, and each metallic fill material portion may include W, Cu, Al, Co, Ru, Mo, Ta, Ti, TiN, alloys thereof, and/or combinations thereof.

Other suitable metallic liner and metallic fill materials within the contemplated scope of disclosure may also be used. In one embodiment, the first metal via structures 146 and the second metal line structures 148 may be formed as integrated line and via structures by a dual damascene process. The dielectric material layers (136, 138, 140) are herein referred to as lower-lower-level dielectric material layers. The metal interconnect structures (142, 144, 146, 148) formed within in the lower-level dielectric material layers are herein referred to as lower-level metal interconnect structures.

While the disclosure is described using an embodiment in which an array of memory cells may be formed over the second line-and-via-level dielectric material layer 140, embodiments are expressly contemplated herein in which the array of memory cells may be formed at a different metal interconnect level.

An array of transistors (e.g., TFTs) and an array of memory cells (e.g., ferroelectric or other types of memory cells) may be subsequently deposited over the dielectric material layers (136, 138, 140) that have formed therein the metal interconnect structures (142, 144, 146, 148). The set of all dielectric material layer that are formed prior to formation of an array of transistors or an array of memory cells is collectively referred to as lower-level dielectric material layers (136, 138, 140). The set of all metal interconnect structures that is formed within the lower-level dielectric material layers (136, 138, 140) is herein referred to as first metal interconnect structures (142, 144, 146, 148). Generally, first metal interconnect structures (142, 144, 146, 148) formed within at least one lower-level dielectric material layer (136, 138, 140) may be formed over the semiconductor material layer 104 that is located in the substrate 102.

According to an embodiment, transistors may be subsequently formed in a metal interconnect level that overlies that metal interconnect levels that contain the lower-level dielectric material layers (136, 138, 140) and the first metal interconnect structures (142, 144, 146, 148). In one embodiment, a planar dielectric material layer having a uniform thickness may be formed over the lower-level dielectric material layers (136, 138, 140). The planar dielectric material layer is herein referred to as an insulating matrix layer 150. The insulating matrix layer 150 may include a dielectric material such as undoped silicate glass, a doped silicate glass, organosilicate glass, or a porous dielectric material, and may be deposited by chemical vapor deposition. The thickness of the insulating matrix layer 150 may be in a range from 20 nm (i.e., 200 angstrom) to 300 nm (i.e., 3000 angstrom), although lesser and greater thicknesses may also be used.

Generally, interconnect-level dielectric layers (such as the lower-level dielectric material layer (136, 138, 140)) containing therein the metal interconnect structures (such as the first metal interconnect structures (142, 144, 146, 148)) may be formed over semiconductor devices. The insulating matrix layer 150 may be formed over the interconnect-level dielectric layers. Other passive devices may be formed in BEOL processes. For example various capacitors, inductors, resistors, and integrated passive devices may be utilized with other BEOL devices.

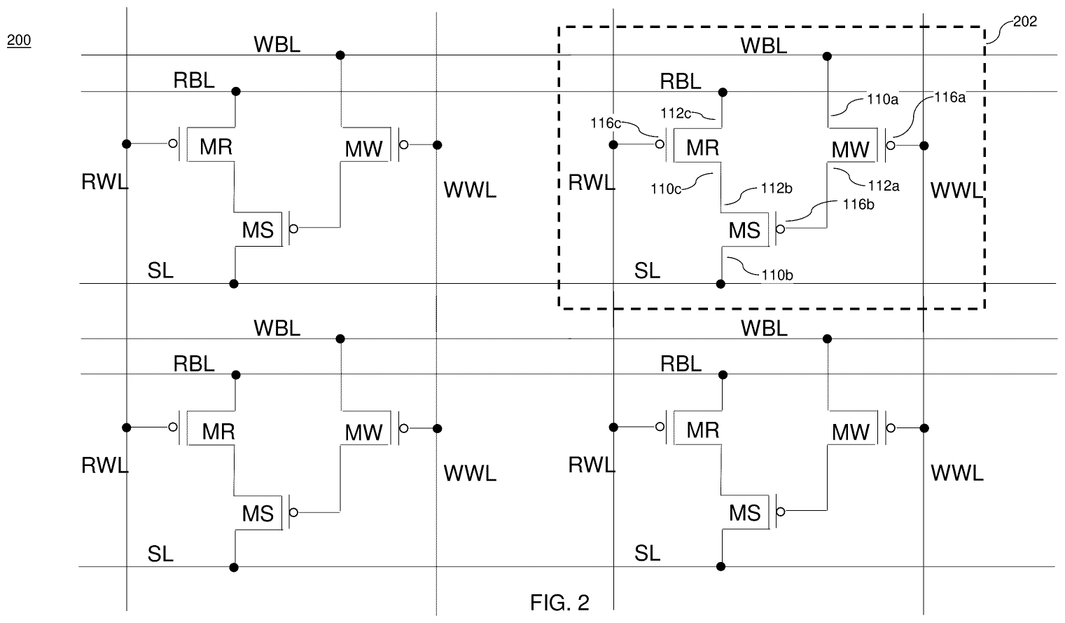

FIG. 2 is a schematic illustration of a portion of a memory array 200, according to various embodiments. The memory array 200 may include a plurality of memory cells 202. Each memory cell 202 may include a write access transistor MW, a storage transistor MS, and a read access transistor RW. The memory array 200 may also include a read bit line RBL, a read word line RWL, a write bit line WBL, a write word line WWL, and a source line SL.

The write access transistor MW may include a first source electrode 110a, a first drain electrode 112a, and a first gate 116a. The first gate 116a of the write access transistor MW may be electrically connected to the write word line WWL and the first source electrode 110a of the write access transistor MW may be electrically connected to the write bit line WBL. The storage transistor MS may include a second source electrode 110b, a second drain electrode 112b, and a second gate 116b. The second gate 116b of the storage transistor MS may be electrically connected to the first drain electrode 112a of the write access transistor MW, and the second source electrode 110b of the storage transistor MS may be electrically connected to the source line SL. The read access transistor MR may include a third source electrode 110c, a third drain electrode 112c, and a third gate 116c. The second drain electrode 112b of the storage transistor MS may be electrically connected to the third source electrode 110c of the read access transistor MR. The third gate 116c of the read access transistor MR may be electrically connected to the read word line RWL, and the third drain electrode 112c of the read access transistor MR may be electrically connected to the read bit line RBL.

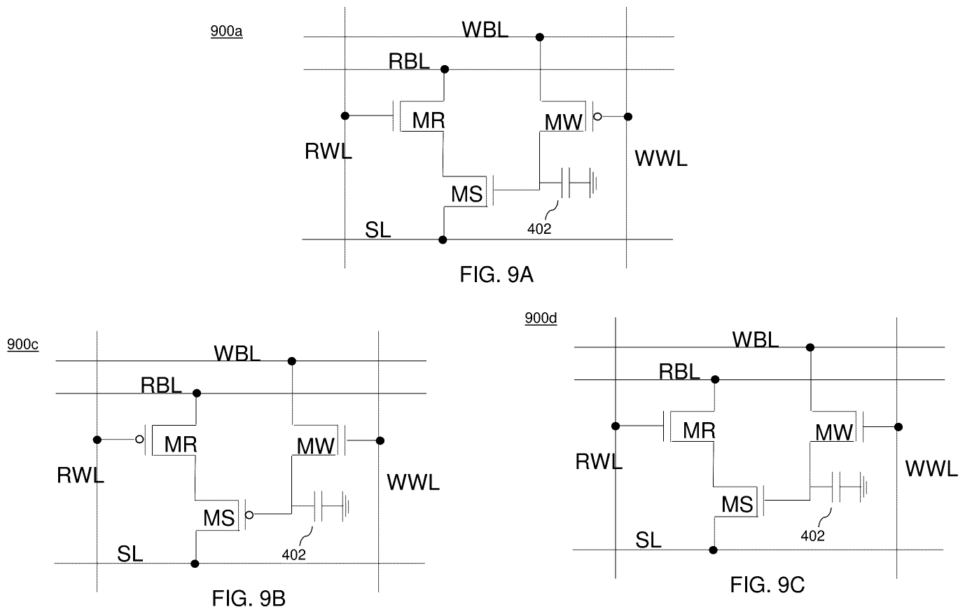

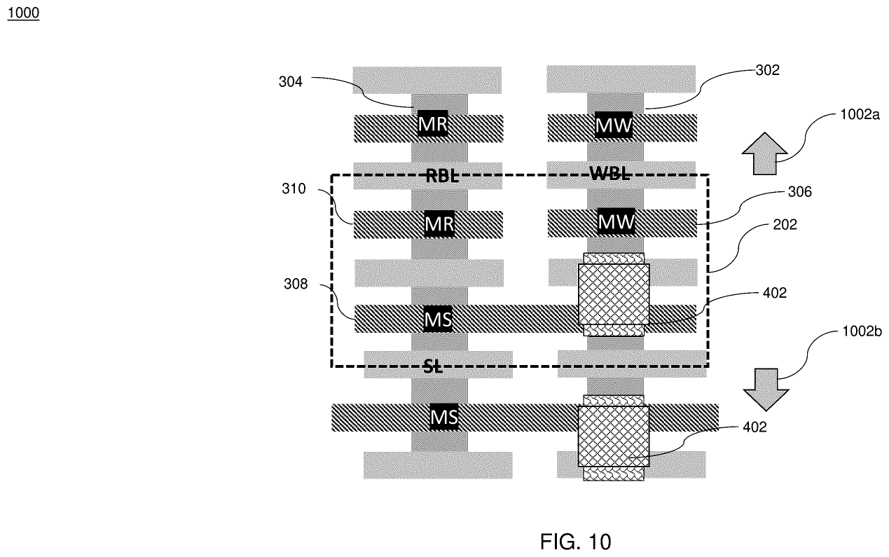

As shown in FIG. 2, the write access transistor MW, the storage transistor MS, and the read access transistor MR may be implemented as PMOS devices. In other embodiments, one or more of the write access transistor MW, the storage transistor MS, and the read access transistor MR may be implemented as NMOS devices (e.g., see FIGS. 9A to 9C and Tables 1 to 4). Writing, storing, and reading data from the memory cell 202 may be performed as follows.

To write a data value to the memory cell 202, the write access transistor MW may be activated by applying a low voltage (e.g., ground (GND)) to the first gate 116a of the write access transistor MW by applying the low voltage to the write word line WWL. Activating the write access transistor MW thereby forms a conductive path between the first source electrode 110a of the write access transistor MW and the first drain electrode 112a of the write access transistor. Activating the write access transistor MW allows charge to flow along the conductive path to thereby establish a voltage corresponding to a voltage that is applied to the write bit line WBL. A low voltage (e.g., GND) may be applied to the write bit line WBL to represent a logical zero “0” value and a high voltage (e.g., VDD) may be applied to the write bit line WBL to represent a logical one “1” value. In this way, a “0” or “1” data value may be written to the memory cell 202.

The data that is written to the memory cell 202 may be stored by deactivating the write access transistor MW by applying a high voltage (e.g., VDD) to the first gate 116a of the write access transistor MW (i.e., by applying a high voltage to the write word line WWL). In this way, the conductive path between first source electrode 110a of the write access transistor MW and the first drain electrode 112a of the write access transistor MW may be switched off (i.e., an open circuit configuration may be established). The charge distribution that was established when the write access transistor MW was activated may thereby be maintained. The charge distribution that was established during the write operation may be stored in the parasitic capacitance associated with the second gate 116b.

A non-destructive read operation may be performed as follows. The read bit line RBL may be initially held at a low voltage (e.g., GND) and the second source electrode 110b of the storage transistor MS may be held at a high voltage (e.g., VDD) by maintaining the source line SL at the high voltage. The read access transistor MR may be activated by applying a low voltage (e.g., GND) to the read word line RWL, which thereby activates the third gate 116c. In this regard, a conductive path may be formed between the third source electrode 110c and the third drain electrode 112c of the read access transistor MR. If a “1” value is stored in the memory cell 202 then the second gate 116b of the storage transistor MS will be at a high voltage and the storage transistor MS will thereby be deactivated. As such, there will be no conductive path between the second source electrode 110b and the second drain electrode 112b of the storage transistor MS. As such, a conductive path will not be formed between the source line SL and the read bit line RBL. As such, the read bit line RBL will be maintained at a low voltage. Thus, in instances in which the read bit line RBL remains at a low voltage upon activation of the read access transistor MR, the stored value may be determined to be a “1” value.

In contrast, in instances in which a “0” value is stored in the memory cell 202 then the second gate 116b of the storage transistor MS will be at a low voltage and the storage transistor MS may thereby be activated. As such, a conductive path may be formed between the second source electrode 110b of the storage transistor MS and the second drain electrode 112b of the storage transistor MS. Consequently, since the read access transistor is also activated, there may also be a conductive path between the source line SL and the read bit line RBL. Since the source line SL is held at a high voltage (e.g., VDD) and the read bit line RBL is initially held at a low voltage (e.g., GND) current may flow from the source line SL to the read bit line RBL causing the voltage on the read bit line RBL to increase. The increased voltage on the read bit line RBL may then be detected by a sense amplifier. Thus, in instances in which the voltage on the read bit line RBL increases upon activation of the read access transistor MR, the stored value may be determined to be a “0” value. As mentioned above, the read operation is non-destructive because the voltage of the second gate 116b of the storage transistor MS is not altered during the read operation.

The data value that is written to the memory cell 202 may be stored by holding each of the write access transistor MW and the read access transistor MR in a deactivated state by respectively holding the write word line WWL and the read word line RWL at a high voltage (e.g., VDD). In general, the data must be periodically refreshed (i.e., re-written) due to the presence of leakage currents that act to alter the amount of charge that is stored in the memory cell 202. For example, in instances in which a “0” value is stored on the memory cell 202, the second gate 116b of the storage transistor MS may be initially set to a low value (e.g., GND). However, because the source line SL and the write word line WWL may be held at a high value (e.g., VDD) charge may leak into the second gate 116b of the storage transistor MS from the source line SL and the write word line WWL, which may be each held at high voltage. As such, the voltage of the second gate 116b may tend to increase over time causing the memory cell 202 to lose the store value.

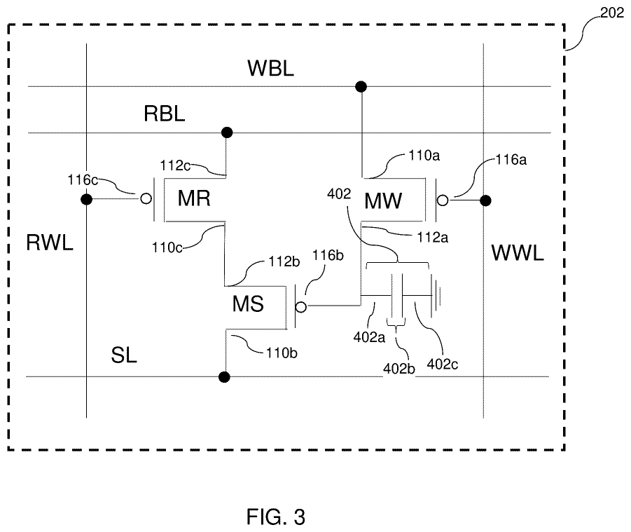

Leakage currents between the source line SL and the read bit line RBL may be reduced by maintaining the read bit line RBL at a high voltage (e.g., VDD), while the data is being held. In this way, the source line SL, the read word line RWL, and the read bit line RBL may all be maintained at a high voltage thereby reducing leakage currents and effectively reducing power dissipation due to leakage currents (i.e., there is little or no current if there is no voltage difference). The write bit line WBL may be held at a low voltage (e.g., GND) during a hold operation to reduce leakage currents when a “0” value is stored. However, when a “1” value is stored, leakage currents may flow from the second gate 116b of the storage transistor MS to the write bit line WBL. As such, both stored values of “0” and “1” may degrade over time due to leakage currents. Various embodiments, described below (e.g., with reference to FIGS. 3 to 7J) introduce capacitive elements to increase the amount of charge that may be stored in the memory cell 202, thereby reducing the refresh rate of the memory cell 202. The presence of capacitive elements may further act to reduce leakage currents and power dissipation.

FIG. 3 is a schematic illustration of a memory cell 202 having a capacitive element 402, according to various embodiments. As described in greater detail below, the capacitive element 402 may include a first terminal 402a, capacitor structure 402b, and a second terminal 402c. The first terminal 402a may be coupled to the first drain electrode 112a and the second gate 116b. The second terminal 402c may be coupled to a voltage source or to a ground terminal (GND). In this way, a voltage difference between the first terminal 402a and the second terminal 402c may cause charge to be stored on the capacitor structure 402b. The ability to store charge on the capacitor structure 402b may act to reduce leakage currents, power dissipation, and a memory refresh rate.

As shown in FIGS. 2 and 3, the memory cell 202 may have an asymmetric layout that provides a space for the capacitive element 402 that is not occupied by other components of the memory cell 202. In this way, the capacitive element 402 may be placed in an area that may otherwise be considered wasted space. As such, the capacitive element 402 may be added to the memory cell 202 without increasing an area occupied by the components of the memory cell. Therefore, embodiment memory cells disclosed herein may therefore be incorporated with only minor modification of existing array designs.

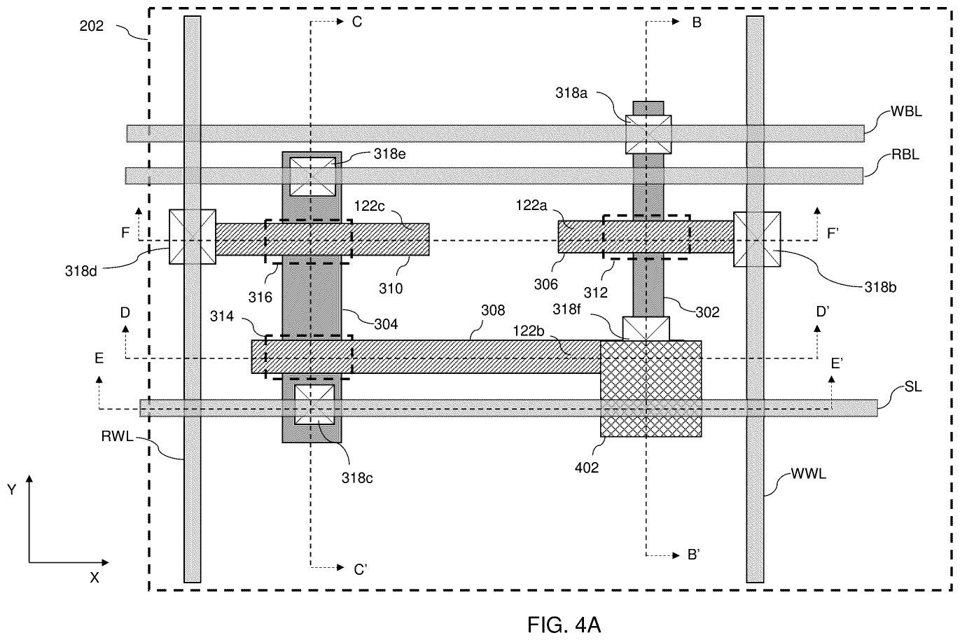

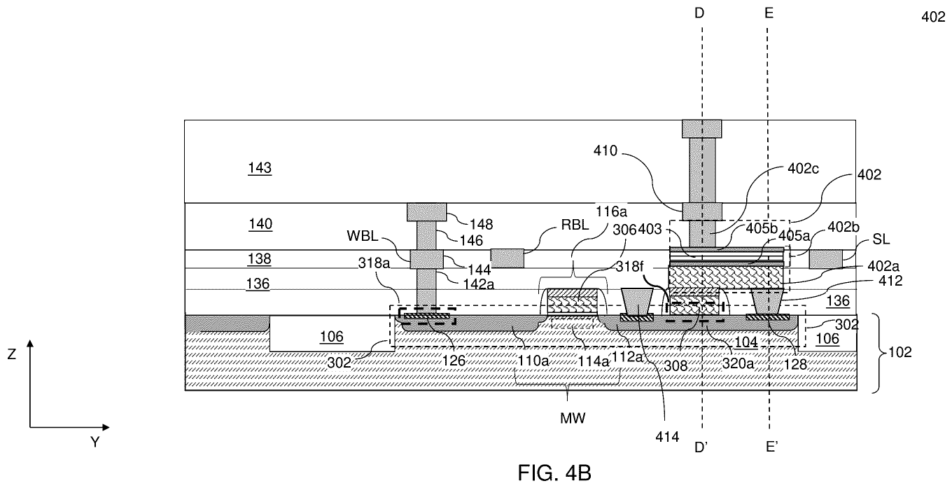

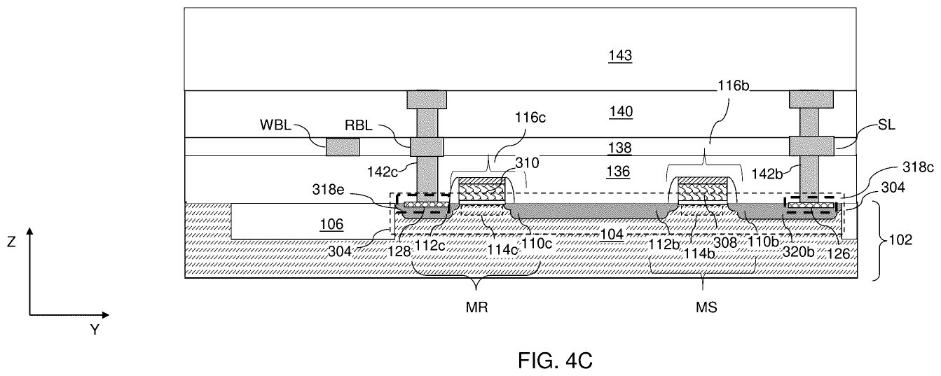

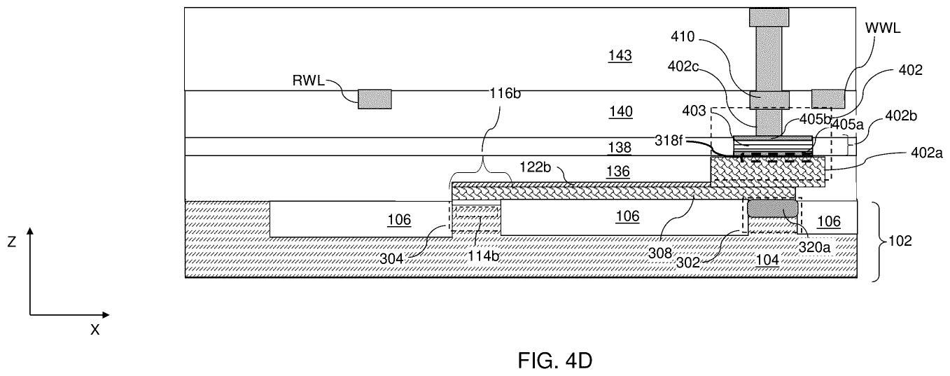

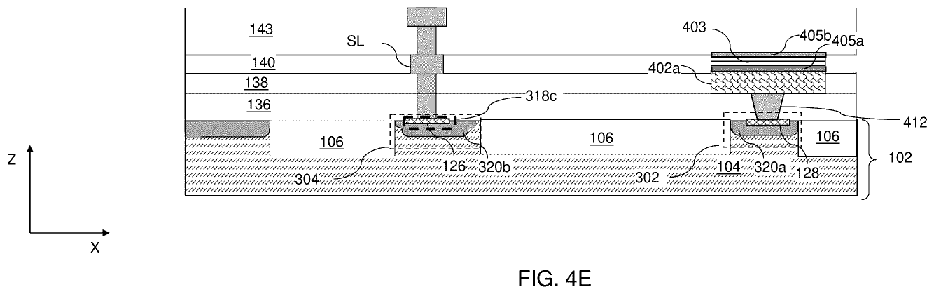

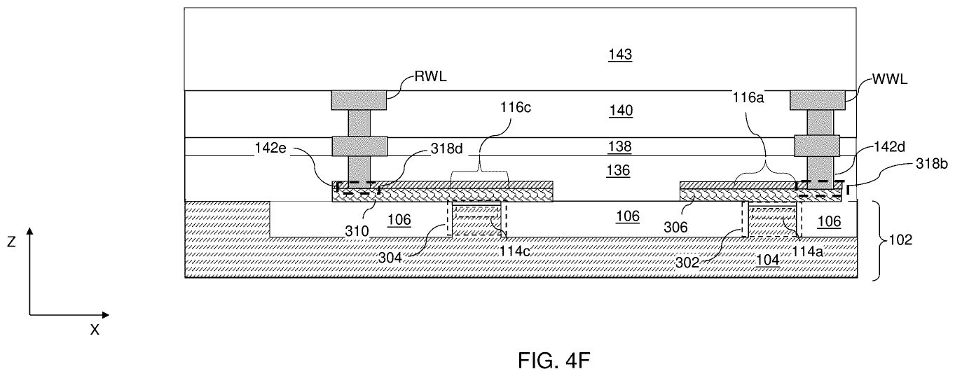

FIG. 4A is a top view of a memory cell 202 having a capacitive element 402, and FIGS. 4B, 4C, 4D, 4E, and 4F are vertical cross-sectional views along lines B-B′, C-C′, D-D′, E-E′, and F-F′, respectively, of the memory cell of FIG. 4A, according to various embodiments. The memory cell 202 may include a first oxide definition region 302 (i.e., a first active region) formed on a substrate 102 (e.g., see FIG. 1) and a second oxide definition region 304 (i.e., a second active region) formed on the substrate 102. As shown, the first oxide definition region 302 and the second oxide definition region 304 may each be formed as a rectangular area having a width along a first direction (e.g., the X direction) and a length along a second direction (e.g., the Y direction). In some embodiments, first oxide definition region 302 and the second oxide definition region 304 may have a common width, while in other embodiments the first oxide definition region 302 and the second oxide definition region 304 may have different widths. The first oxide definition region 302 and the second oxide definition region 304 may each include suitably doped semiconductor wells such that transistors may be formed therein (e.g., see FIG. 1 and related description), as described in greater detail with reference to FIGS. 4B and 4C, respectively, below.

The memory cell 202 may further include a first continuous polysilicon region 306 formed over the first oxide definition region 302. As described above with reference to FIG. 1, the first continuous polysilicon region 306 may include a heavily doped polysilicon material that may be configured to act as a conductor. For example, the first continuous polysilicon region 306 may have a minimum resistivity of approximately 300 μohm-cm. The resistivity of the first continuous polysilicon region 306 may be reduced by formation of a first low-resistivity, shunting polycide layer 122a over the first continuous polysilicon region 306 (e.g., see FIG. 1 and related description). The first low-resistivity, shunting polycide layer 122a may include various polycide materials including CoSi₂ (18-25 μohm-cm), HfSi₂ (45-50 μohm-cm), MoSi₂ (100 μohm-cm), NiSi₂ (50-60 μohm-cm), Pd₂Si (30-50 μohm-cm), PtSi (28-35 μohm-cm), TaSi₂ (35-55 μohm-cm), TiSi₂ (13-25 μohm-cm), WSi₂ (70 μohm-cm), and ZrSi₂ (35-40 μohm-cm), etc. Other suitable polycide materials within the contemplated scope of disclosure may also be used.

The memory cell 202 may further include a second continuous polysilicon region 308 formed over the first oxide definition region 302 and the second oxide definition region 304 such that the second continuous polysilicon region 308 may be electrically connected to the first oxide definition region 302, as described in greater detail with reference to FIGS. 4B and 4D, below. The memory cell 202 may further include a third continuous polysilicon region 310 formed over the second oxide definition region 304, as described in greater detail with reference to FIGS. 4C and 4F, below. Each of the second continuous polysilicon region 308 and the third continuous polysilicon region 310 may include heavily doped polysilicon material that may be configured to act as a conductor. The second continuous polysilicon region 308 and the third continuous polysilicon region 310 may have similar properties to the first continuous polysilicon region 306, including a minimum resistivity of approximately 300 μohm-cm.

The resistivity of the second continuous polysilicon region 308 and the third continuous polysilicon region 310 may be lowered by forming a second low-resistivity, shunting polycide layer 122b, and a third low-resistivity, shunting polycide layer 122c on the second continuous polysilicon region 308 and on the third continuous polysilicon region 310, respectively. The second polycide layer 122b and the third polycide layer 122c may each include similar polycide materials as describe above with reference to the first polycide layer 122a.

A first portion 312 of the first continuous polysilicon region 306 may be configured to be overlapping with the first oxide definition region 302 to thereby form a first gate 116a (i.e., a gate of a write access transistor MW, see FIGS. 2 and 3), as described in greater detail with reference to FIG. 1, above, and FIGS. 4B an 4F, below. A second portion 314 of the second continuous polysilicon region 308 may be configured to be overlapping with the second oxide definition region 304 to thereby form a second gate 116b (i.e., a gate of a storage transistor MS, see FIGS. 2 and 3), as described in greater detail with reference to FIG. 1, above, and FIGS. 4C and 4D, below. Similarly, a third portion 316 of the third continuous polysilicon region 310 may be configured to be overlapping with the second oxide definition region 304 to thereby form a third gate 116c (i.e., a gate of a read access transistor MR, see FIGS. 2 and 3), as described in greater detail with reference to FIG. 1, above, and FIGS. 4C and 4F, below.

The capacitive element 402 may be formed so as to be electrically connected to the first oxide definition region 302 as well as to the second continuous polysilicon region 308. As such, the capacitive element 402 may be coupled to the first drain electrode 112a and the second gate 116b, as described above with reference to FIG. 3, and as described in greater detail with reference to FIGS. 4B, 4D, and 4E, below. The second oxide definition region 304 may be configured such that a second drain electrode 112b (i.e., the drain of the storage transistor MS) may be electrically connected to the third source electrode 110c (i.e., the source of the read access transistor MR, e.g., see FIGS. 2, 3) as shown, for example, in FIG. 4C.

The memory cell 202 may further include a read bit line RBL, a read word line RWL, a write bit line WBL, a write word line WWL, and a source line SL. A first contact 318a may be formed at a first end of the first oxide definition region 302. The first contact 318a may be configured to be electrically coupled with a first source electrode 110a (i.e., a source of the write access transistor MW). The first contact 318a may be electrically connected to the write bit line WBL such that the first source electrode 110a may be electrically connected to the write bit line WBL as shown, for example, in FIGS. 2, 3, and 4B, and described in greater detail, below.

A second contact 318b may be formed at a first end of the first continuous polysilicon region 306. The second contact 318b may be electrically connected to the write word line WWL such that the first gate 116a may be electrically connected to the write word line WWL as shown, for example, in FIGS. 2, 3, and 4F. A third contact 318c may be formed at a first end of the second oxide definition region 304. The third contact 318c may be configured to be electrically coupled with the second source electrode 110b (i.e., the source electrode of the storage transistor MS, e.g., see FIGS. 2 and 4C). The third contact 318c may be electrically connected to the source line SL such that the second source electrode 110b of the storage transistor MS may be electrically connected to the write source line SL.

A fourth contact 318d may be formed at a first end of the third continuous polysilicon region 310. The fourth contact 318d may be electrically connected to the read word line RWL (e.g., see FIGS. 2, 3, and 4F) such that the third gate 116c of the read access transistor MR may be electrically connected to the read word line RWL. A fifth contact 318e may be formed at a second end of the second oxide definition region 304. The fifth contact 318e may be electrically coupled with the third drain electrode 112c of the read access transistor MR (e.g., see FIGS. 2, 3, and 4C). The fifth contact 318e may be electrically connected to the read bit line RBL such that the third drain electrode 112c of the read access transistor MR is electrically connected to the read bit line RBL as shown, for example, in FIGS. 2 and 4C.

The first oxide definition region 302 and the second continuous polysilicon region 308 may be configured such that the first drain electrode 112a (i.e., the drain of the write access transistor MW, e.g., see FIGS. 2, 3, and 4B) may be electrically connected to the second gate 116b (i.e., the gate of the storage transistor MS, e.g., see FIGS. 2, 3, 4C, and 4D). In this regard, a sixth contact 318f (e.g., see FIGS. 4A and 4B) may be formed between the first oxide definition region 302 and the second polysilicon region 308 such that an electrical connection may be made between the first oxide definition region 302 and the second polysilicon region 308, as described in greater detail, below.

FIG. 4B is a vertical cross-sectional view of the memory cell 202 of FIG. 4A defined by the cross section B-B′ shown in FIG. 4A, according to various embodiments. The vertical dashed lines marked D-D′ and E-E′ in FIG. 4B indicate the respective intersections of the vertical planes defining the respective D-D′ and E-E′ cross-sections in FIG. 4A with the vertical plane defining the B-B′ cross section of FIG. 4B.

The structure may include a substrate 102 having a semiconductor material layer 104. The write access transistor MW, having a first gate 116a, a first source electrode 110a, a first semiconductor channel 114a, and a first drain electrode 112a, may be formed in the semiconductor material layer 104 (e.g., see FIG. 1 and related description).

Various metal interconnect structures (142a, 144, 146, 148, 402b, 410) may be formed in a plurality of dielectric material layers (136, 138, 140, 143). The metal interconnect structures (142a, 144, 146, 148, 402b, 410) may include a first metal via structure 142a formed in the first interconnect-level dielectric material layer 136, a first metal line structure 144 formed in the first interconnect-level dielectric material layer 138, a second metal via structure 146 formed in a lower portion of the second interconnect-level dielectric material layer 140, and a second metal line structure 148 formed in an upper portion of the second interconnect-level dielectric material layer 140. In this embodiment, the first metal line structure 144 may be configured as the write bit line WBL. The read bit line RBL and the source line SL may also be formed in the first interconnect-level dielectric material layer 138. In other embodiments, the write bit line WBL, the read bit line RBL, and the source line SL may be formed in other dielectric material layers.

The first contact 318a may be formed at a first end of the first oxide definition region 302 and may be configured to be electrically coupled with the first source electrode 110a of the write access transistor MW. In this regard, a source-side metal-semiconductor alloy region 126 may be formed at the surface of the semiconductor material layer 104 and may include various materials such as TiSi, NiSi, CoSi, and other silicides. The source-side metal-semiconductor alloy region 126 may from an electrically conductive pathway between the first metal via structure 142a and the first source electrode 110a. In this way, the write bit line WBL may be electrically connected to the first source electrode 110a.

The sixth contact 318f may be formed between the first oxide definition region 302 and the second polysilicon region 308 such that an electrical connection may be made between the first oxide definition region 302 and the second polysilicon region 308. In this regard, a portion of the second polysilicon region 308, which includes an electrically conducting heavily doped polysilicon material, may be formed directly on a first doped semiconductor well 320a of the first oxide definition region 302 such that an electrical connection is formed. In further embodiments, the sixth contact 318f may further include a metal-semiconductor alloy region (not shown) similar to the drain-side metal-semiconductor alloy region 128 formed with the first contact 318a. Thus, the first drain electrode 112a of the write access transistor MW and the second gate 116b (i.e., the gate of the storage transistor MS, e.g., see FIG. 4C) may be electrically connected.

As shown in FIG. 4B, the capacitive element 402 may include a capacitor structure 402b that includes a dielectric element 403 sandwiched between a first conductor 405a and a second conductor 405b. The first conductor 405a may be electrically coupled to a first terminal 402a and the second conductor 405b may be electrically coupled to a second terminal 402c. The first terminal 402a may be configured to form an electrically conductive path with the second continuous polysilicon region 308. For example, the first terminal 402a may be a fourth continuous heavily doped polysilicon region that is in direct contact with a portion of the second continuous polysilicon region 308. The first terminal 402a may further include one or more polycide regions (not shown) configured to reduce a resistivity of the first terminal 402a. The second terminal 402c may be a via structure that is electrically connected to a metallic line 410. The second continuous polysilicon region 308 may be electrically connected to the first drain electrode 112a (i.e., the drain of the write access transistor MW), as shown in FIG. 4B, and connected to the second gate 116b, as shown in FIG. 4C. As such, the capacitor structure may thereby be connected to the second gate 116b and the first drain 112a.

The capacitive element 402 may further be electrically connected to a metal via structure 412 that may be electrically connected to first doped semiconductor well 320a of the first oxide definition region 302. As shown, the metal via structure 412 may further include a drain-side metal-semiconductor alloy region 128 that may be formed at the surface of the semiconductor material layer 104 and that may provide an electrically conductive pathway between the metal via structure 412 and the first doped semiconductor well 320a of the first oxide definition region 302. As such, the first terminal 402a of the capacitive element 402 may be further electrically connected to the first drain electrode 112a (i.e., the drain of the write access transistor MW) through the electrically conductive pathways formed between metal via structure 412 and the doped semiconductor portion 320.

As mentioned above, the second terminal 402c of the capacitive element 402 may further be connected to a voltage source. In this regard, the second terminal 402c may be electrically connected with the metal line 410 structure that may be connected to the voltage source. The voltage source may be configured to hold the metal line 410 and thus the second terminal of the capacitor structure 402b at a predetermined voltage. For example, the predetermined voltage may be a high voltage (e.g., VDD) or the predetermined voltage may be a low voltage (e.g., GND). In this way, the second terminal 402c of the capacitor structure 402b may be held at a predetermined voltage. As such, the capacitor structure 402b may be configured to store an electrical charge based on a voltage difference between a voltage of the first terminal 402a (i.e., the voltage of the first drain electrode 112a and the second gate 116b) and a voltage of the second terminal 402c (i.e., the voltage of the metal line 410 that is maintained by the voltage source). The memory cell 202 may further include one or more metal via structures 414 that act as floating contacts (i.e., that are not connected to a voltage source). The one or more metal via structure 414 may act as a further capacitive element to thereby store additional charge.

FIG. 4C is a further vertical cross-sectional view of the memory cell 202 of FIG. 4A defined by the cross section C-C′ shown in FIG. 4A, according to various embodiments. The structure may also be formed in the substrate 102 having a semiconductor material layer 104, as described above with reference to FIG. 4B.

The storage transistor MS, having a second gate 116b, a second source electrode 110b, a second semiconductor channel 114b, and a second drain electrode 112b, may be formed in the semiconductor material layer 104 (e.g., see FIGS. 1 and 4B and related description). The second gate 116b may include a portion of the second polysilicon region 308 that overlaps with a portion of the semiconductor material layer 104 such that the second channel region 114b may be formed under the second gate 116b. The read access transistor MR having a third gate 116c, a third source electrode 110c, a third semiconductor channel 114c, and a third drain electrode 112c may also be formed in the semiconductor material layer 104. The third gate 116c may include a portion of the third polysilicon region 310 that overlaps with a portion of the semiconductor material layer 104 such that the third channel region 114c may be formed under the third gate 116c.

Various metal interconnect structures (142b, 142c) may be formed in a plurality of dielectric material layers (136, 138, 140, 143). As described above, the write bit line WBL, the read bit line RBL, and the source line SL may be formed in the first interconnect-level dielectric material layer 138. While FIG. 4C illustrates the write bit line WBL, the read bit line RBL, and the source line SL formed in the first interconnect-level dielectric material layer 138, each of the write bit line WBL, the read bit line RBL, and the source line SL may be formed in any of the plurality of dielectric material layers (136, 138, 140, 143). Moreover, each of the write bit line WBL, the read bit line RBL, and the source line SL may be formed in the same or different ones of the plurality of dielectric material layers (136, 138, 140, 143).

The third contact 318c may be formed at a first end of the second oxide definition region 304 and may be configured to be electrically coupled with the second source electrode 110b (e.g., see FIGS. 2, 3, 4A and 4C) of the storage transistor MS. In this regard, a source-side metal-semiconductor alloy region 126 may be formed at the surface of the semiconductor material layer 104. The source-side metal-semiconductor alloy region 126 may form an electrically conductive pathway between the metal via structure 142b and a second doped semiconductor well 320b of the semiconductor material layer 104 that forms the second source electrode 110b (i.e., the source electrode of the storage transistor MS). The third contact 318c may be electrically connected to the source line SL such that the second source electrode 110b may be electrically connected to the source line SL.

The fifth contact 318e may be formed at a second end of the second oxide definition region 304 and may be electrically coupled with the third drain electrode 112c (i.e., the drain electrode of the read access transistor MR, e.g., see FIGS. 2, 3, 4A and 4C). In this regard, a drain-side metal-semiconductor alloy region 128 may be formed at the surface of the semiconductor material layer 104. The drain-side metal-semiconductor alloy region 128 may form an electrically conductive pathway between the metal via structure 142c and the third drain electrode 112c. The fifth contact 318e may be electrically connected to the read bit line RBL such that the third drain electrode 112c may be electrically connected to the read bit line RBL.

FIG. 4D is a further vertical cross-sectional view of the memory cell of FIG. 4A defined by the cross section D-D′ shown in FIG. 4A, according to various embodiments. This further vertical cross sectional view illustrates that the first oxide definition region 302 and the second oxide definition region 304 maybe separated from one another by shallow trench isolation structures 106. Further, the sixth contact 318f (e.g., see FIGS. 4A and 4B) may be formed between the first oxide definition region 302 and the second polysilicon region 308 such that an electrical connection may be made between the first oxide definition region 302 and the second polysilicon region 308. In this regard, a portion of the second polysilicon region 308 may be formed so as to be overlapping with the first doped semiconductor well 320a.

Also shown is a cross-sectional view of a portion of the second polysilicon region 308 that overlaps with a portion of the second oxide definition region 304 so as to form the second gate 116b (i.e., the gate of the storage transistor MS) having the second semiconductor channel 114b formed under the second gate 116b. The read word line RWL and the write word line WWL may also be formed as metal line structures formed in the third interconnect-level dielectric material layer 140, as shown. While FIG. 4D illustrates the read word line RWL and the write word line WWL formed in the third interconnect-level dielectric material layer 140, each of the read word line RWL and the write word line WWL may be formed in any of the plurality of dielectric material layers (136, 138, 140, 143). Moreover, each of the read word line RWL and the write word line WWL may be formed in the same or different ones of the plurality of dielectric material layers (136, 138, 140, 143).

As described above, the capacitor structure 402b may include a dielectric element 403 sandwiched between a first conductor 405a and a second conductor 405b. The first terminal 402a may be formed as a fourth heavily doped polysilicon region that forms an electrical connection with the second polysilicon region 308. The second terminal 402c may be a via structure that connects to a metal line 410. The metal line 410 may be further connected to a voltage source (e.g., VDD or GND). In this way, the capacitive element 402 may be electrically connected with the second gate 116b and with the first drain electrode 112a (e.g., see FIGS. 4A and 4B).

FIG. 4E is a further vertical cross-sectional view of the memory cell of FIG. 4A defined by the cross section E-E′ shown in FIG. 4A, according to various embodiments. As described above, the third contact 318c may be formed at a first end of the second oxide definition region 304 and may be configured to be electrically coupled with the second source electrode 110b (i.e., the source electrode of the storage transistor MS, e.g., see FIGS. 2, 3, 4A and 4C). In this regard, a source-side metal-semiconductor alloy region 126 may be formed at the surface of the semiconductor material layer 104. The source-side metal-semiconductor alloy region 126 may form an electrically conductive pathway between the metal via structure 142b and the second doped semiconductor well 320b of the semiconductor material layer 104 that forms the second source electrode 110b (i.e., the source electrode of the storage transistor MS). The third contact 318c may be electrically connected to the source line SL such that the second source electrode 110b (e.g., see FIGS. 4A and 4C) may be electrically connected to the source line SL.

Also, as indicated in FIG. 4B, the vertical plane defining the E-E′ cross-section includes cross-sectional views of the first oxide definition region 302 and the second oxide definition region 304 and further intersects the substrate 102, the first doped semiconductor well 320a, the drain-side metal-semiconductor alloy region 128, the first terminal 402a, and the capacitor structure 402b, which includes the dielectric element 403 sandwiched between the first conductor 405a and the second conductor 405b.

FIG. 4F is a further vertical cross-sectional view of the memory cell of FIG. 4A defined by the cross section F-F′ shown in FIG. 4A, according to various embodiments. As shown, a portion of the first polysilicon region 306 overlaps with a region of the first oxide definition region 302 to thereby form the first gate 116a having the first semiconductor channel 114a formed under the first gate 116a. Similarly, a portion of the third polysilicon region 310 overlaps with a region of the second oxide definition region 304 to thereby form the third gate 116c (i.e., the gate of the read access transistor MR) having the third semiconductor channel region 114c formed under the third gate 116c.

The second contact 318b may be formed to be electrically connected to the write word line WWL. In this regard, a metal via structure 142d may be formed so as to make an electrically conductive pathway with the first polysilicon region 306. In this way, the first gate 116a may be electrically connected to the write word line WWL that may be formed in the second interconnect-level dielectric material layer 140. Similarly, the fifth contact 318e may be formed to be electrically connected to the read word line RWL. In this regard, a metal via structure 142e may be configured to make an electrically conductive pathway with the third polysilicon region 310. In this way, the third gate 116c may be electrically connected to the read word line RWL that may be formed in the second interconnect-level dielectric material layer 140. While FIG. 4E illustrates the read word line RWL and the write word line WWL formed in the third interconnect-level dielectric material layer 140, each of the read word line RWL and the write word line WWL may be formed in any of the plurality of dielectric material layers (136, 138, 140, 143). Moreover, each of the read word line RWL and the write word line WWL may be formed in the same or different ones of the plurality of dielectric material layers (136, 138, 140, 143).

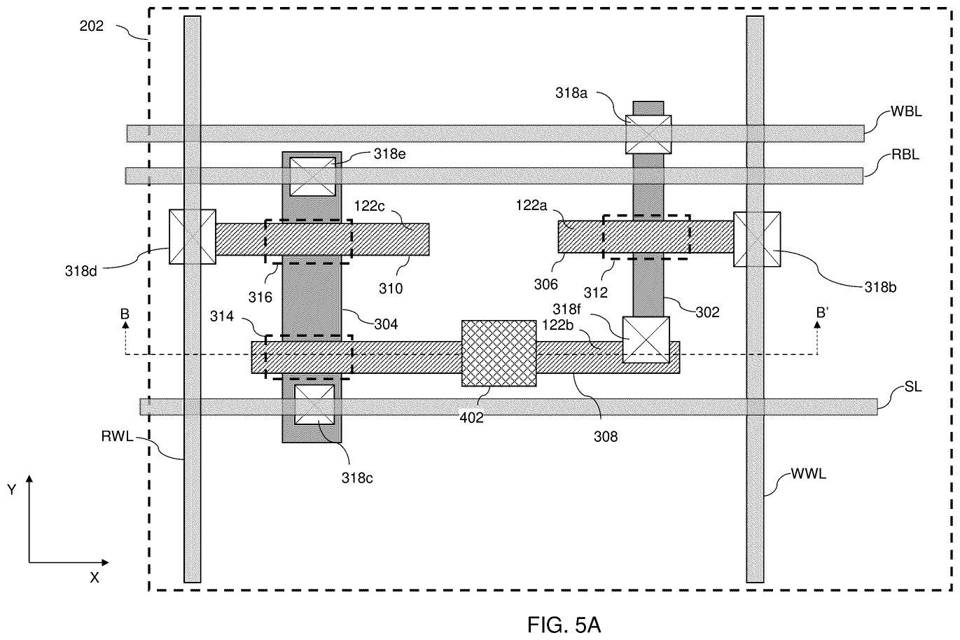

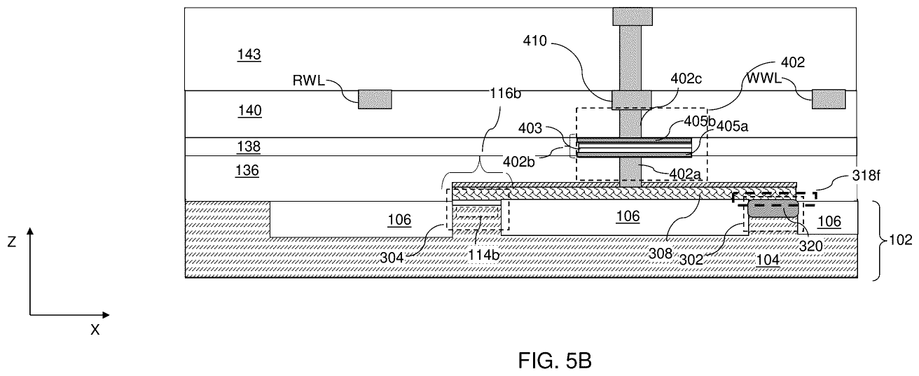

FIG. 5A is a top view of another embodiment memory cell 202 having a capacitive element 402, and FIG. 5B is a vertical cross-sectional view of the memory cell 202 of FIG. 5A defined by the cross section B-B′ shown in FIG. 5A, according to various embodiments. The capacitive element 402 may be formed so as to be electrically connected to the second continuous polysilicon region 308. As such, the capacitive element 402 may be electrically connected to the second gate 116b (i.e., the gate of the storage transistor MS, e.g., see FIG. 4C). Further, since an electrically conductive pathway may be formed between the second continuous polysilicon region 308 and the first oxide definition region 302, as described above, the capacitive element 402 may also be electrically connected to the first drain electrode 112a (e.g., see FIGS. 4B and 4D).

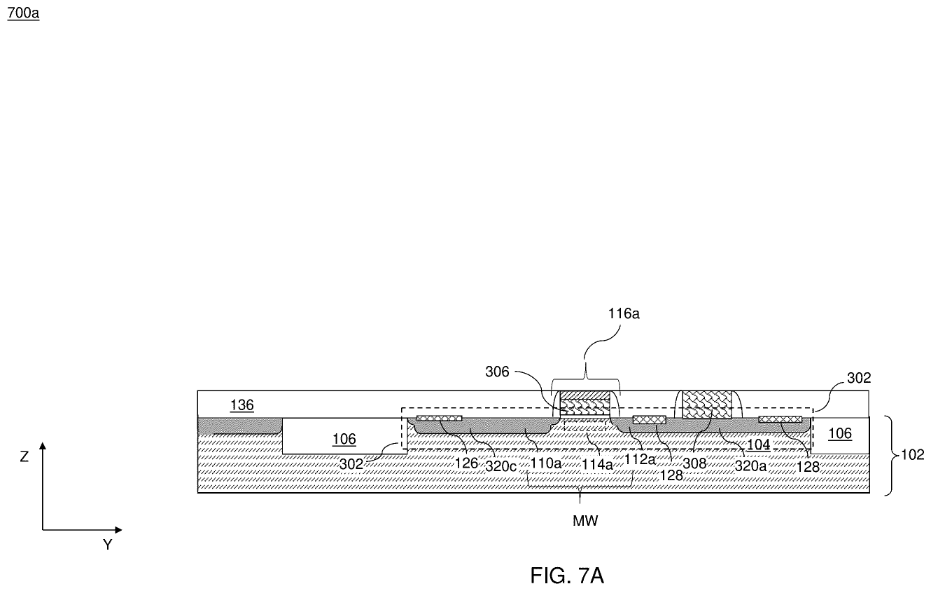

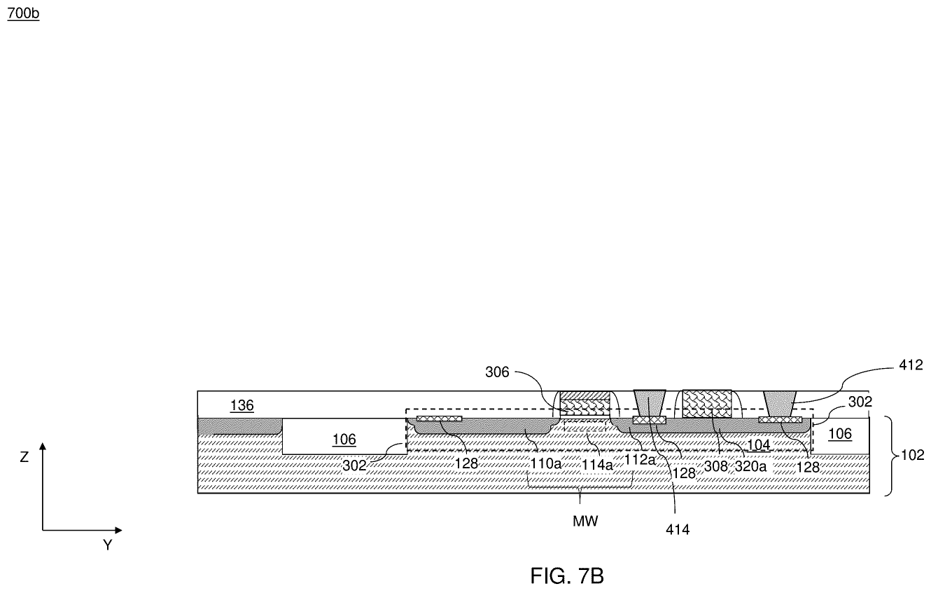

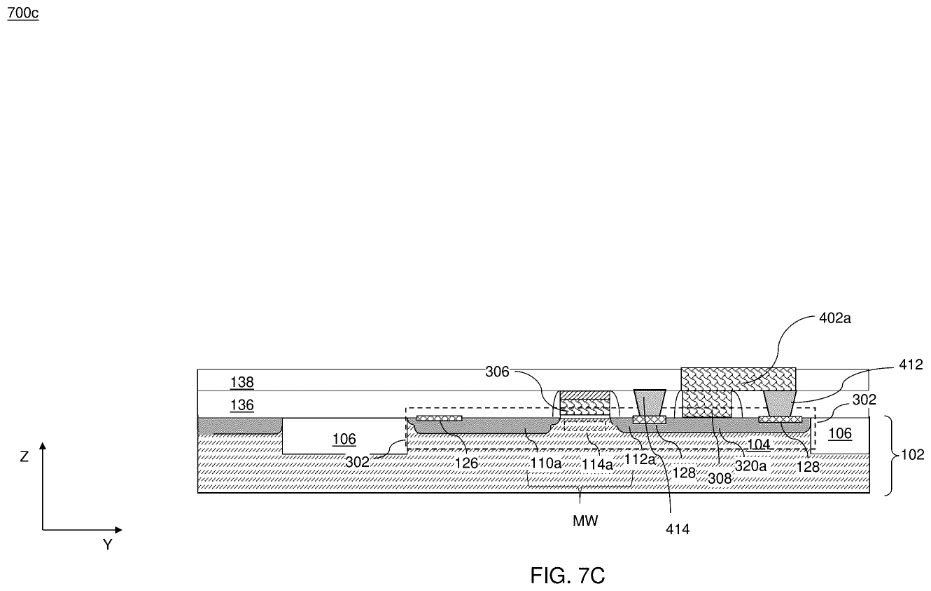

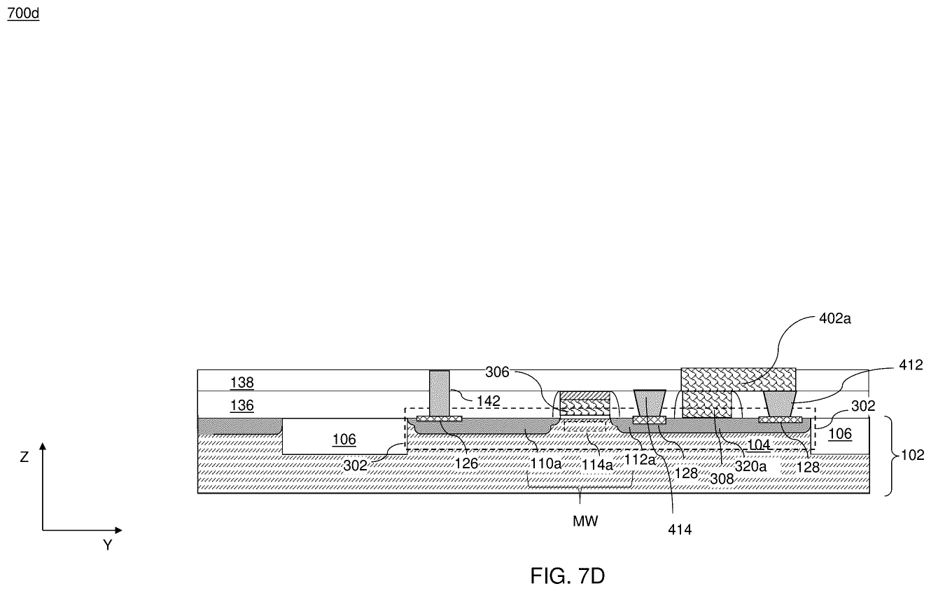

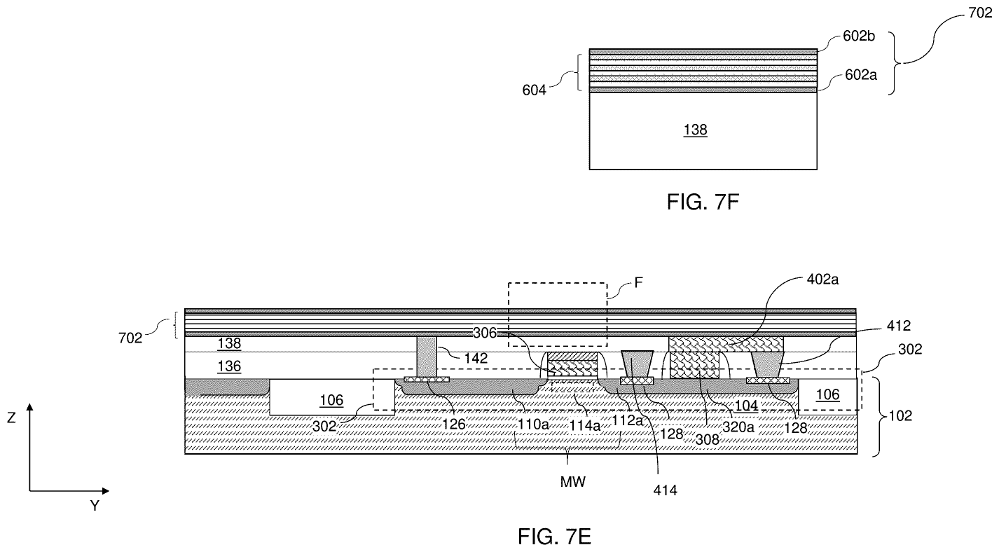

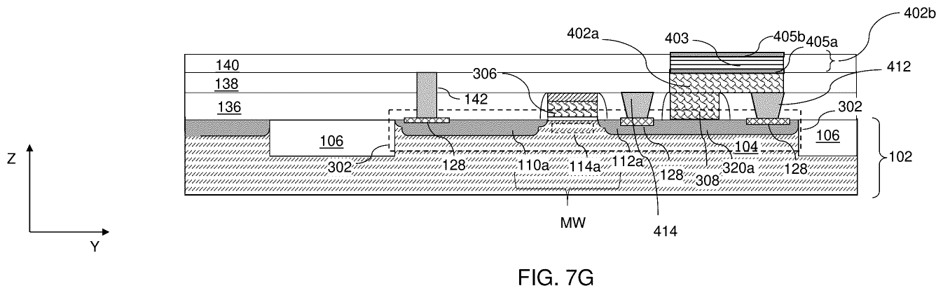

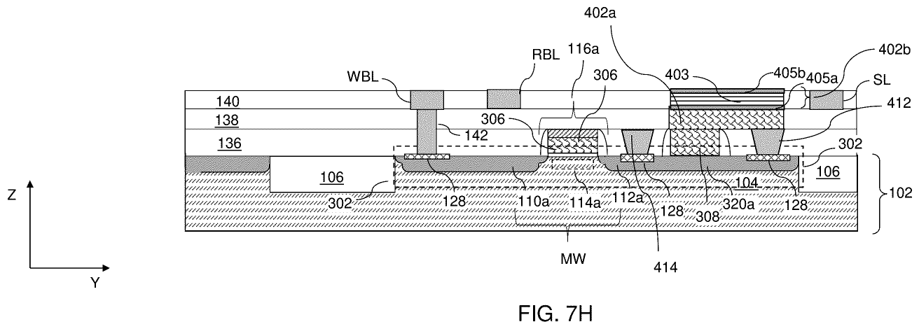

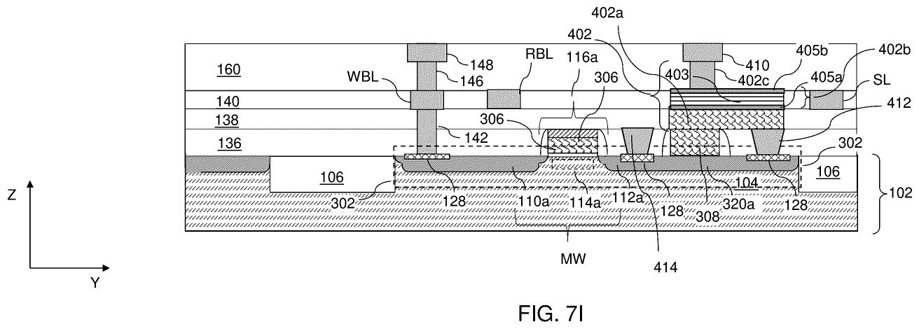

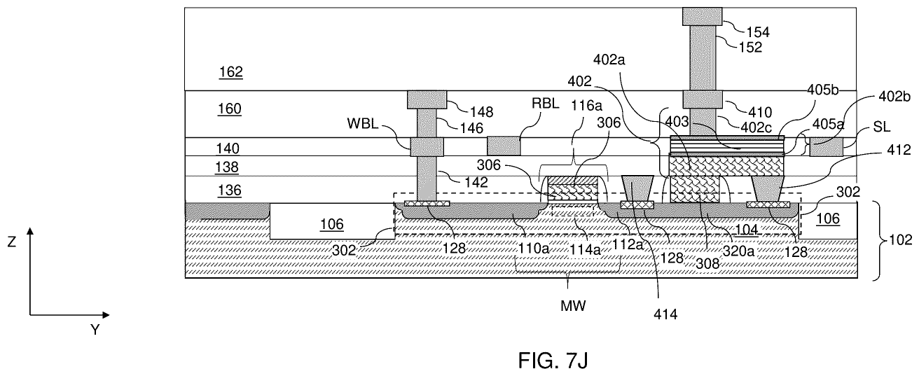

As shown in FIG. 5B, the capacitive element 402 may include a first terminal 402a, a capacitor structure 402b, and a second terminal 402c. The capacitor structure 402b may include a dielectric element 403 sandwiched between a first conductor 405a and a second conductor 405b. The first terminal 402a may be configured to form an electrically conductive pathway with the second continuous polysilicon region 308. For example, the first terminal 402a may be a metal via structure that is in direct contact with a portion of the second continuous polysilicon region 308. The dielectric element 403 may include a single layer of a dielectric material. Alternatively, the dielectric element 403 may include an alternating multi-layer stack of dielectric materials, as described in greater detail with reference to FIGS. 7E and 7F, below. The first conductor 405a may be electrically connected to the first terminal 402a and the second conductor 405b may be electrically connected to the second terminal 402c.

The second terminal 402c may further be connected to a voltage source. In this regard, the second terminal 402c may be electrically connected with a metal line 410 that is connected to the voltage source. The voltage source may be configured to hold the metal line 410 at a predetermined voltage. For example, the predetermined voltage may be a high voltage (e.g., VDD) or the predetermined voltage may be a low voltage (e.g., GND). In this way, the second terminal 402c of the capacitive element 402 may be held at a predetermined voltage. As such, the capacitive element 402 may be configured to store an electrical charge based on a voltage difference between a voltage of the first terminal 402a (i.e., the voltage of the first drain 112a of the write access transistor MW and the second gate 116b of the storage transistor MS) and a voltage of the second the second terminal 402c (i.e., the voltage of the metal line 410 that is maintained by the voltage source).

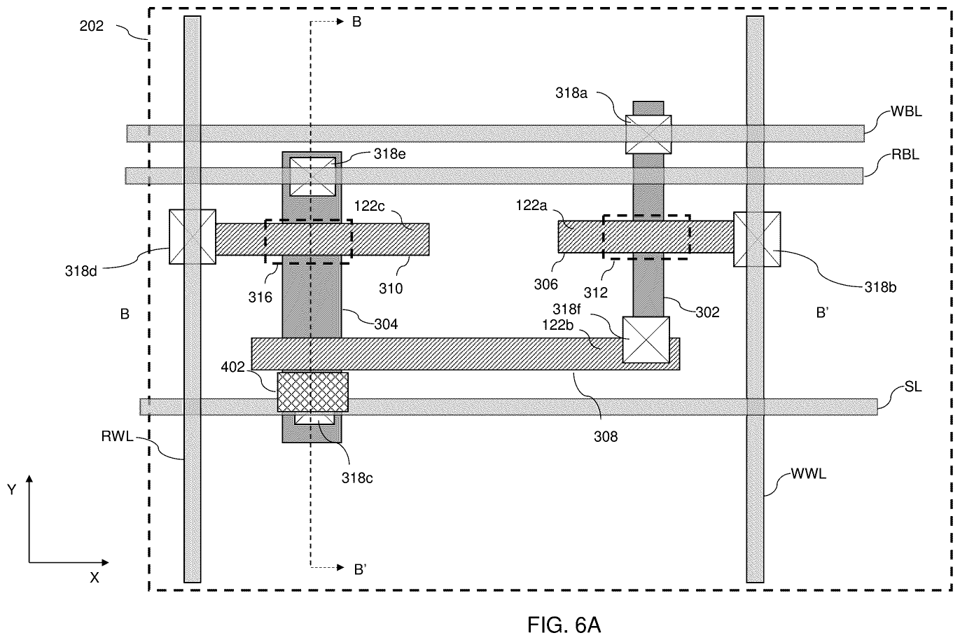

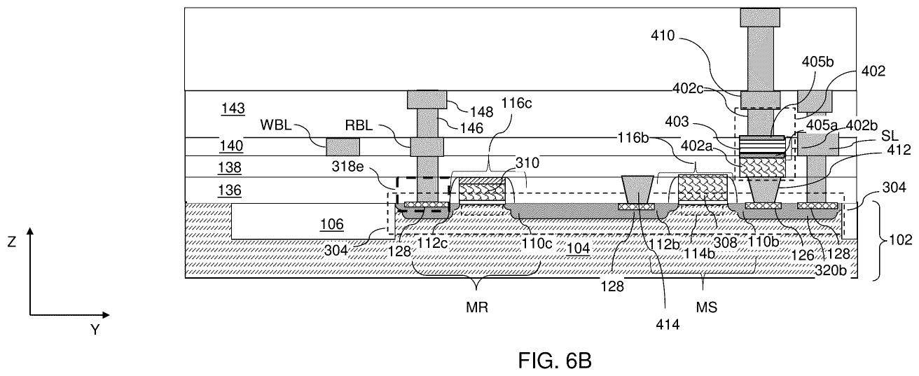

FIG. 6A is a top view of another embodiment memory cell 202 having a capacitive element 402, and FIG. 6B is a vertical cross-sectional view of the memory cell 202 of FIG. 6A defined by the cross section B-B′ shown in FIG. 6A, according to various embodiments. The capacitive element 402 may be formed so as to be electrically connected to the second oxide definition region 304. As shown in FIG. 6B, the capacitive element 402 may include a first terminal 402a, a capacitor structure 402b, and a second terminal 402c. The capacitor structure 402b may include a dielectric element 403 sandwiched between a first conductor 405a and a second conductor 405b. The dielectric element 403 may include a single layer of a dielectric material. Alternatively, the dielectric element 403 may include an alternating multi-layer stack of dielectric materials, as described in greater detail with reference to FIGS. 7E and 7F, below.

The first conductor 405a may be electrically connected to the first terminal 402a and the second conductor 405b may be electrically connected to the second terminal 402c. The first terminal 402a may be configured to form an electrically conductive pathway with a metal via structure 412 that may be electrically connected to the second doped semiconductor well 320b. As shown, the metal via structure 412 may be coupled to a source-side metal-semiconductor alloy region 126 that may be formed at the surface of the semiconductor material layer 104 and that may provide an electrically conductive pathway between the metal via structure 412 and the second doped semiconductor well 320b.

The second terminal 402c may further be connected to a voltage source. In this regard, the second terminal 402c may be electrically connected with a metal line 410 that is connected to the voltage source. The voltage source may be configured to hold the metal line 410 at a predetermined voltage. For example, the predetermined voltage may be a high voltage (e.g., VDD) or the predetermined voltage may be a low voltage (e.g., GND). In this way, the second terminal 402c of the capacitive element 402 may be held at a predetermined voltage. As such, the capacitive element 402 may be configured to store an electrical charge based on a voltage difference between a voltage of the first terminal 402a (i.e., the voltage of the second source electrode 110b) and a voltage of the second terminal 402c (i.e., the voltage of the metal line 410 that is maintained by the voltage source).

The memory cell 202 may further include one or more metal via structures 414 that act as floating contacts (i.e., that are not connected to a voltage source). The one or more metal via structure 414 may act as a further capacitive element to thereby store additional charge. In some embodiments, the presence of the capacitive element 402 and/or the one or more metal via structures 414 may act to reduce leakage currents between the second source electrode 110b and the second gate 116b.

FIG. 7A is a vertical cross-sectional view of an intermediate structure that may be used in the formation of a memory cell, according to various embodiments. The vertical cross-sectional view of FIG. 7A is defined by the cross section B-B′ shown in FIG. 4B. As such, the intermediate structure shown in FIG. 7A may be used in the formation of the structure shown in FIG. 4B, described in greater detail, above. The intermediate structure shown in FIG. 7A includes the first oxide definition region 302 that has been formed in a surface region of the substrate 102. As such, the first oxide definition region 302 may include a first source electrode 110a and a first drain electrode 112a (i.e., source and drain of the write access transistor MW, respectively). The semiconductor material layer 104 further may include a first semiconductor channel 114a (i.e., the semiconductor channel of the write access transistor MW).

As described above, the first continuous polysilicon region 306 overlaps with the first oxide definition region 302 and thereby forms the first gate 116a of the write access transistor MW. The second continuous polysilicon region 308 overlaps with the first doped semiconductor well 320a of the semiconductor material layer 104 to thereby form an electrically conductive pathway between the first drain electrode 112a and the second oxide definition region 304 (e.g., see FIGS. 4A, 4B, and 4D). The intermediate structure shown in FIG. 7A may further include a source-side metal-semiconductor alloy region 126 and drain-side metal-semiconductor alloy regions 128 that may be formed in surface regions of the semiconductor material layer 104. The intermediate structure shown in FIG. 7A may further include a first interconnect-level dielectric material layer 136 formed over the substrate 102.

FIG. 7B is a vertical cross-sectional view of a further intermediate structure that may be used in the formation of a memory cell, according to various embodiments. The vertical cross-sectional view of FIG. 7B is the same as that of FIG. 7A and is defined by the cross section B-B′ shown in FIG. 4B. The intermediate structure shown in FIG. 7B may be formed from the intermediate structure of FIG. 7A by forming a first metal via structure 412 and a second metal via structure 414 in the first interconnect-level dielectric material layer 136. In this regard, via cavities (not shown) may be selectively etched in the first interconnect-level dielectric material layer 136. In this regard, a patterned photoresist (not shown) may be formed over the first interconnect-level dielectric material layer 136 and the patterned photoresist may be used to perform an anisotropic etch to thereby form via cavities in the first interconnect-level dielectric material layer 136. The etch may be allowed to proceed until a top surface of the drain-side metal-semiconductor alloy region 128 is exposed. The patterned photoresist may then be removed by ashing or dissolution with a solvent.

The first metal via structure 412 and the second metal via structure 414 may then be formed by deposition of a conductive material, which may be a combination of a metallic liner (such as a metallic nitride or a metallic carbide) and a metallic fill material. Each metallic liner may include TiN, TaN, WN, TiC, TaC, and WC, and each metallic fill material portion may include W, Cu, Al, Co, Ru, Mo, Ta, Ti, TiN, alloys thereof, and/or combinations thereof. Other suitable metallic liner and metallic fill materials are within the contemplated scope of disclosure. The conductive material may be deposited to thereby form an electrically conductive pathway with the drain-side metal-semiconductor alloy region 128. Excess conductive material may then be removed over a surface of the first interconnect-level dielectric material layer 136 using a planarization process (e.g., chemical mechanical planarization).

FIG. 7C is a vertical cross-sectional view of an intermediate structure that may be used in the formation of a memory cell, according to various embodiments. The intermediate structure shown in FIG. 7C may be formed from the intermediate structure shown in FIG. 7B by formation of a first terminal 402a. In this regard, the first terminal 402a may be formed by deposition of a blanket layer of polysilicon (not shown) over the first interconnect-level dielectric material layer 136. The blanket layer of polysilicon may then be pattered (e.g., using a patterned photoresist) to thereby form the first terminal 402a having an electrically conductive pathway with the second continuous polysilicon region 308 and with the first metal via structure 412. A second interconnect-level dielectric material layer 138 may then be formed over the first interconnect-level dielectric material layer 136.

Alternatively, the second interconnect-level dielectric material layer 138 may be first deposited and patterned to form a trench (not shown) having exposed top portions of the second continuous polysilicon region 308 and the first via structure 412. The trench may then be filled with polysilicon to thereby form the first terminal 402a. In further embodiments, a liftoff process may be performed in which a patterned photoresist (not shown), having an opening corresponding to a position of the (yet to be formed) first terminal 402a, is formed over the interconnect-level dielectric material layer 136. Polysilicon may then be deposited over the patterned photoresist. The patterned photoresist may then be removed leaving the first terminal 402a formed over the first interconnect-level dielectric material layer 136. The second interconnect-level dielectric material layer 138 may then be formed over the first interconnect-level dielectric material layer 136.

FIG. 7D is a vertical cross-sectional view of an intermediate structure that may be used in the formation of a memory cell, according to various embodiments. The intermediate structure shown in FIG. 7D may be formed from the intermediate structure shown in FIG. 7C by formation of a third via structure 142. In this regard, a via cavity (not shown) may be selectively etched through the second interconnect-level dielectric material layer 138 and through first interconnect-level dielectric material layer 136. A patterned photoresist (not shown) may be formed over the second interconnect-level dielectric material layer 138 and the patterned photoresist may be used to perform an anisotropic etch to thereby form the via cavity in the second interconnect-level dielectric material layer 138 and the first interconnect-level dielectric material layer 136. The etch may be allowed to proceed until a top surface of the source-side metal-semiconductor alloy region 126 is exposed. The patterned photoresist may then be removed by ashing or dissolution with a solvent.

The third metal via structure 142 may then be formed by deposition of a conductive material, which may be a combination of a metallic liner (such as a metallic nitride or a metallic carbide) and a metallic fill material. Each metallic liner may include TIN, TaN, WN, TiC, TaC, and WC, and each metallic fill material portion may include W, Cu, Al, Co, Ru, Mo, Ta, Ti, TiN, alloys thereof, and/or combinations thereof. Other suitable metallic liner and metallic fill materials are within the contemplated scope of disclosure. The conductive material may be deposited to thereby form an electrically conductive pathway with the source-side metal-semiconductor alloy region 126. Excess conductive material may then be removed over a surface of the second interconnect-level dielectric material layer 138 using a planarization process (e.g., chemical mechanical planarization).

FIG. 7E is a vertical cross-sectional view of a further intermediate structure that may be used in the formation of a memory cell, and FIG. 7F shows an enlarged portion of the intermediate structure of FIG. 7E, according to various embodiments. The intermediate structure may be formed from the intermediate structure shown in FIG. 7D by formation of a multilayer structure 702 over the second interconnect-level dielectric material layer 138. The multilayer structure 702 may include a dielectric layer 604 sandwiched a first metallic layer 602a and a second metallic layer 602b. The first metallic layer 602a and the second metallic layer 602b may include one or more of TiN and TaN. Various other conducting materials may be used for the first metallic layer 602a and the second metallic layer 602b in other embodiments.

The dielectric layer 604 may be a single layer of a dielectric material or the dielectric layer 604 may be a multilayer stack including two or more dielectric materials. In various embodiments, the dielectric layer 604 may be a high-k dielectric material. For example, the high-k dielectric layer may include one or more of hafnium oxide, hafnium lanthanum oxide, hafnium silicon oxide, hafnium tantalum oxide, hafnium titanium oxide, hafnium zirconium oxide, zirconium oxide, titanium oxide, aluminum oxide, and hafnium dioxide-alumina. In other embodiments, the dielectric layer 604 may be include two or more of the above-described high-k dielectric materials. In other embodiments, the dielectric layer 604 may include various other dielectric materials such as silicon oxide, silicon nitride, silicon carbide, etc.

FIG. 7G is a vertical cross-sectional view of a further intermediate structure that may be used in the formation of a memory cell, according to various embodiments. The intermediate structure shown in FIG. 7G may be formed from the intermediate structure shown in FIG. 7E by patterning the multilayer structure 702 to thereby form the capacitor structure 402b. In this regard, a blanket layer of photoresist material (not shown) may be formed over the multilayer structure 702. The blanket layer of photoresist may then be patterned using photolithographic techniques to form a patterned photoresist. The patterned photoresist may then be used in an anisotropic etch process to remove unmasked portions of the multilayer structure 702 to thereby form the capacitor structure 402b having a dielectric element 403 sandwiched between a first conductor 405a and a second conductor 405b. The patterned photoresist may then be removed by ashing or by dissolution with a solvent. A third interconnect-level dielectric material layer 140 may then be formed over the second interconnect-level dielectric material layer 138.

FIG. 7H is a vertical cross-sectional view of a further intermediate structure that may be used in the formation of a memory cell, according to various embodiments. The intermediate structure of FIG. 7H may be formed from the intermediate structure of FIG. 7G by formation of metal lines in the third interconnect-level dielectric material layer 140. For example, the word bit line WBL, the read bit line RBL, and the source line SL may be formed by etching line trenches (not shown) in the third interconnect-level dielectric material layer 140 and filling the line trenches with a conductive material. The conductive material may be a combination of a metallic liner (such as a metallic nitride or a metallic carbide) and a metallic fill material. Each metallic liner may include TIN, TaN, WN, TiC, TaC, and WC, and each metallic fill material portion may include W, Cu, Al, Co, Ru, Mo, Ta, Ti, TiN, alloys thereof, and/or combinations thereof. Other suitable metallic liner and metallic fill materials are within the contemplated scope of disclosure.

FIGS. 7I and 7J are vertical cross-sectional views of further intermediate structures, respectively, that may be used in the formation of a memory cell, according to various embodiments. The intermediate structure of FIG. 7I may be formed from the intermediate structure of FIG. 7H by formation of a fourth interconnect-level dielectric material layer 160 and formation of additional metal interconnect structures (146, 148, 402c, 410) in the fourth interconnect-level dielectric material layer 160. For example, via cavities (not shown) and line trenches (not shown) may be formed in the fourth interconnect-level dielectric material layer 160 by performing an anisotropic etching process. The metal interconnect structures (146, 148, 402c, 410) may be formed by depositing a conductive material.

The conductive material may be a combination of a metallic liner (such as a metallic nitride or a metallic carbide) and a metallic fill material. Each metallic liner may include TIN, TaN, WN, TiC, TaC, and WC, and each metallic fill material portion may include W, Cu, Al, Co, Ru, Mo, Ta, Ti, TiN, alloys thereof, and/or combinations thereof. Other suitable metallic liner and metallic fill materials are within the contemplated scope of disclosure.

The intermediate structure shown in FIG. 7J may be formed from the intermediate structure shown in FIG. 7I by formation of a fifth interconnect-level dielectric material layer 162 and formation of additional metal interconnect structures (152, 154) in the fifth interconnect-level dielectric material layer 162. As shown in FIGS. 7I and 7J, the second terminal 402c may be configured to form an electrically conductive contact with the capacitor structure 402b. For example, as described above, the second terminal 402c may be electrically connected with the second conductor 405b of the capacitor structure 402b. Further, the metal line 410 may be electrically coupled to a voltage source to thereby control a voltage of the second terminal 402c.

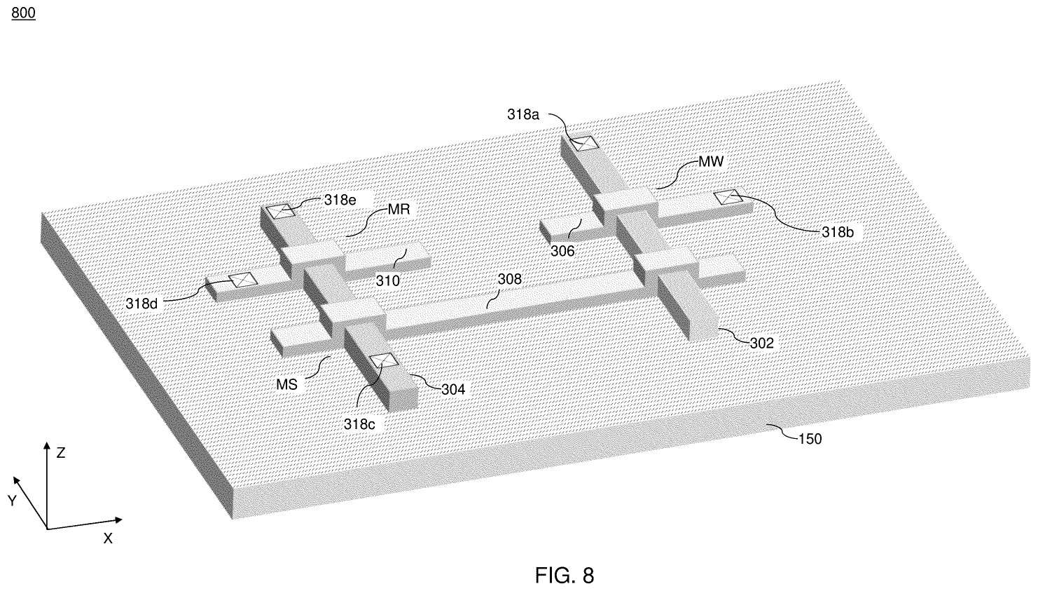

FIG. 8 is a three-dimensional view of a memory cell 800, according to various embodiments. The memory cell 800 may be formed in a BEOL process such that the write access transistor MW, the storage transistor MS, and the read access transistor MR are formed as FinFET transistors. As shown, the first oxide definition region 302 and the second oxide definition region 304 may be formed as a fin-shaped structures on a substrate 150. The substrate 150 may be an insulating matrix layer 150 (e.g., see FIG. 1 and related description) that is formed in a BEOL process. The first continuous polysilicon region 306 may be configured to overlap with the first definition region 302 to thereby form a gate of the write access transistor MW.

The second continuous polysilicon region 308 may be configured to overlap both the first oxide definition region 302 and the second oxide definition region 304. As in previous embodiments, described above, the second continuous polysilicon region 308 may form an electrically conductive connection with the first oxide definition region and may overlap with the second oxide definition region 304 to thereby form a gate of the storage transistor MS. The third continuous polysilicon region 310 may overlap with the second oxide definition region 304 to thereby form the gate of the read access transistor MR.

A first contact 318a may be formed at a first end of the first oxide definition region 302, a second contact 318b may be formed at a first end of the first continuous polysilicon region 306, a third contact 318c may be formed at a first end of the second oxide definition region 304, a fourth contact 318d may be formed at a first end of the third continuous polysilicon region 310, and a fifth contact 318e may be formed at a second end of the second oxide definition region 304. As described above (e.g., see FIG. 4A), the first contact 318a may be connected to the write bit line WBL, the second contact 318b may be connected to the write word line WWL, the third contact 318c may be connected to the source line SL, the fourth contact 318d may be connected to the read word line RWL, and the fifth contact 318e may be connected to the read bit line RBL. Additional embodiments may include one or more capacitive elements 402 that may be formed over the memory 800 using the methods described above with reference to FIGS. 4A to 7J.

FIGS. 9A to 9C are schematic illustrations of memory cells 900a to 900c, respectively, having various configurations of a write access transistor MW, a storage transistor MS, and a read access transistor MR, according to various embodiments. The use of one type of transistor vs. another (e.g., pFET vs. nFET) may have advantages in reducing leakage currents and thereby reducing refresh rates. In each of the memory cells, a capacitive element is shown connected to ground. In other embodiments, the capacitive element may be held at other voltages (e.g., VDD).

The memory cells 202, described above with reference to FIGS. 2 and 3, are configured such that each of the write access transistor MW, the storage transistor MS, and the read access transistor MR is configured as a pFET device in which each device (i.e., is activated by placing a low (e.g., GND) voltage on the gate). The voltages placed on the write bit line WBL, the write word line WWL, the read word line RWL, the read bit line RBL, and the source line SL for the various read, write, and hold operations for the memory cell 900a are summarized in Table 1, below.

TABLE 1

| | WBL | WWL | RWL | RBL | SL |
|---|---|---|---|---|---|
| Hold | GND | VDD | VDD | VDD | VDD |
| Read | GND | VDD | GND | GND | VDD |
| Write 0 | GND | GND | VDD | VDD | VDD |
| Write 1 | VDD | GND | VDD | VDD | VDD |

The memory cell 900a, of FIG. 9A, is configured such that the write access transistor MW is configured as a pFET device and the storage transistor MS, and the read access transistor MR are each configured as an nFET device (i.e., are activated when a high voltage is applied to the gate). The voltages placed on the write bit line WBL, the write word line WWL, the read word line RWL, the read bit line RBL, and the source line SL for the various read, write, and hold operations for the memory cell 900b are summarized in Table 2, below.

TABLE 2

| | WBL | WWL | RWL | RBL | SL |
|---|---|---|---|---|---|
| Hold | GND | VDD | GND | GND | GND |
| Read | GND | VDD | VDD | VDD | GND |
| Write 0 | GND | GND | GND | GND | GND |
| Write 1 | VDD | GND | GND | GND | GND |

The memory cell 900b, of FIG. 9B, is configured such that the write access transistor MW is configured as an nFET device and the storage transistor MS, and the read access transistor MR are each configured as a pFET device. The voltages placed on the write bit line WBL, the write word line WWL, the read word line RWL, the read bit line RBL, and the source line SL for the various read, write, and hold operations for the memory cell 900c are summarized in Table 3, below

TABLE 3

| | WBL | WWL | RWL | RBL | SL |
|---|---|---|---|---|---|
| Hold | VDD | GND | VDD | VDD | VDD |
| Read | VDD | GND | GND | GND | VDD |
| Write 0 | GND | VDD | VDD | VDD | VDD |
| Write 1 | VDD | VDD | VDD | VDD | VDD |

The memory cell 900c, of FIG. 9C, is configured such that each of the write access transistor MW, the storage transistor MS, and the read access transistor MR is configured as an nFET device in which each device. The voltages placed on the write bit line WBL, the write word line WWL, the read word line RWL, the read bit line RBL, and the source line SL for the various read, write, and hold operations for the memory cell 900d are summarized in Table 4, below

TABLE 4

| | WBL | WWL | RWL | RBL | SL |
|---|---|---|---|---|---|
| Hold | VDD | GND | GND | GND | GND |
| Read | VDD | GND | VDD | VDD | GND |
| Write 0 | GND | VDD | GND | GND | GND |
| Write 1 | VDD | VDD | GND | GND | GND |

FIG. 10 is a schematic illustration of a portion of a memory array 1000 having a high-density configuration, according to various embodiments. The memory array 1000 may include a first oxide definition region 302 and a second oxide definition region 304. Each of the first oxide definition region 302 and the second oxide definition region 304 may be formed as rectangular areas that span a plurality of memory cells 202. As describe above, each memory cell 202 may include a write access transistor MW, a storage transistor MS, and a read access transistor MR. A gate of the write access transistor MW may be formed by an overlap of a first continuous polysilicon region 306 with the first oxide definition region 302. A second continuous polysilicon region 308 may connect the first oxide definition region 302 and the second oxide definition region 304. The second continuous polysilicon region 308 may form a gate of the storage transistor MS and may form an electrically conducting connection with the first oxide definition region 302. Each memory cell 202 may further include a capacitive element 402, as described in greater detail in the context of other embodiments, above.

A source of the write access transistor MW may be electrically connected to a write bit line WBL, a source of the storage transistor MS may be electrically connected to a source line SL, and a drain of the read access transistor may be electrically connected to bit line RBL, as shown. The gate of the write access transistor MW may be electrically connected to a write word line (not shown) and the gate of the read access transistor MR may be connected to a read bit line (not shown). As describe in the context of other embodiments, above, the drain of the storage transistor MS may be connected to the source of the read access transistor MR and the drain of the write access transistor MW may be connected to the gate of the source transistor.

The memory array 1000 may be configured to have a high-density configuration in which each neighboring memory cell 202 is configured as a mirror image of an adjacent memory cell 202. For example, the memory cell 202 may have a first adjacent memory cell in a first direction 1002a and second adjacent memory cell in a second direction 1002b. The first adjacent memory cell in the first direction 1002a may include a write access transistor MW and a read access transistor MR that are located proximate to the corresponding write access transistor MW and the read access transistor MR of the memory cell 202. Similarly, the second adjacent memory cell in the second direction 1002b may include a storage transistor MS and a capacitive element 402 located proximate to the corresponding storage transistor MS and a capacitive element 402 of the memory cell. Such an arrangement may allow for a reduced wiring complexity by allowing proximate devices (e.g., adjacent write access transistors MW, read access transistors MR, and storage transistors MS) to share common lines (e.g., the write bit line WBL, the read bit line RBL, and the source line SL, respectively).

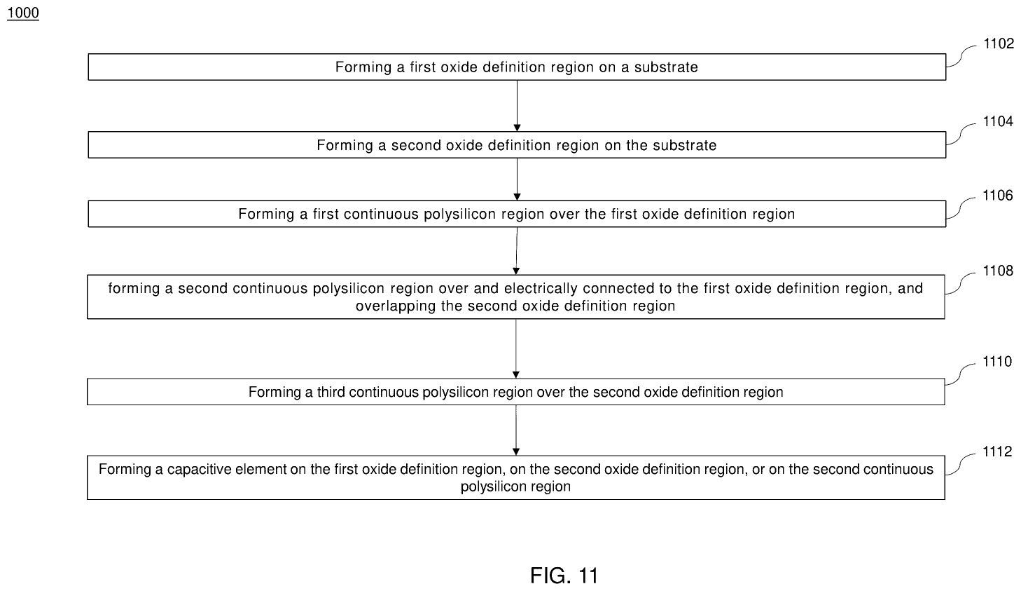

FIG. 11 is a flowchart illustrating a method 1100 of fabricating a memory cell, according to various embodiments. In operation 1102, the method 1100 may include forming a first oxide definition region 302 on a substrate 102 and in operation 1104, the method 1100 may include forming a second oxide definition 304 region on the substrate 102. As describe above, each oxide definition region (302, 304) is an active region in which transistors may be formed at a semiconductor material level 104 in a front-end-of-line (FEOL) process or at a substrate 150 (e.g., see FIGS. 1 and 8) in a BEOL process. In operation 1106, the method 1100 may include forming a first continuous polysilicon region 306 over the first oxide definition region 302. In operation 1108, the method 1100 may include forming a second continuous polysilicon region 308 over and electrically connected to the first oxide definition region 302, and overlapping the second oxide definition region 304. In operation 1110, the method 1100 may include forming a third continuous polysilicon region 310 over the second oxide definition region 304. In operation 1112, the method 1100 may include forming a capacitive element 402 on the first oxide definition region 302, on the second oxide definition region 304, or on the second continuous polysilicon region 308.

According to the method 1100, forming the first continuous polysilicon region 306 may further include configuring a first portion 312 first continuous polysilicon region 306 to overlap with the first oxide definition region 302 to thereby form a first gate 116a of a write access transistor MW (e.g., see FIGS. 4B and 4F). Forming the second continuous polysilicon region 308 may further include configuring a second portion 314 of the second continuous polysilicon region 308 to overlap with the second oxide definition region 304 to thereby form a second gate 116b of a storage transistor MS (e.g., see FIGS. 4C and 4D). Forming the third continuous polysilicon region 310 may further include configuring a third portion 316 of the third continuous polysilicon region 310 to overlap with the second oxide definition region 304 to thereby form a third gate 116c of a read access transistor MR (e.g., see FIGS. 4C and 4F).

The method 1100 may further include forming a read bit line RBL and a read word line RWL, forming a write bit line WBL and a write word line WWL, and forming a source line SL. The method 1100 may further include forming a first contact 318a at a first end of the first oxide definition region 302 to thereby form a first source electrode 110a of the write access transistor MW; electrically connecting the first contact 318a to the write bit line WBL such that the first source electrode 110a is electrically connected to the write bit line WBL.

The method 1100 may further include forming a second contact 318b at a first end of the first continuous polysilicon region 306, electrically connecting the second contact 318b to the write word line WWL such that the first gate 116a is electrically connected to the write word line WWL, forming a third contact 318c at a first end of the second oxide definition region 304 to thereby form a second source electrode 110b of the storage transistor MS and electrically connecting the third contact 318c to the source line SL such that the second source electrode 110b is connected to the source line SL.

The method 1100 may further include forming a fourth contact 318d at a first end of the third continuous polysilicon region 310, electrically connecting the fourth contact 318d to the read word line RWL such that the third gate 116c is electrically connected to the read word line RWL, forming a fifth contact 318e at a second end of the second oxide definition region 304 to thereby form a third drain electrode 112c of the read access transistor MR, and electrically connecting the fifth contact 318e to the read bit line RBL such that the third drain electrode 112c is electrically connected to the read bit line RBL.

According to the method 1100, the first oxide definition region 302 and the second continuous polysilicon region 308 may be configured such that a first drain electrode 112a of the write access transistor MW is electrically connected to the second gate 116b (i.e., that gate of the storage transistor MS). Further, the second oxide definition region 304 may be configured such that a second drain electrode 112b of the storage transistor is electrically connected to a third source electrode 110c of the read access transistor MR.

According to the method 1100, forming the capacitive element 402 may further include forming an interlayer dielectric layer 136 over the first oxide definition region 302, etching the interlayer dielectric layer to thereby form a via cavity, such the etching is allowed to progress until a surface of the first oxide definition region is exposed (e.g., see FIG. 7B and related description), and forming an electrically conducting via 412 in the via cavity such that the electrically conducting via 412 makes electrical contact with the surface of the first oxide definition region 302.

The method 1100 may further include forming a multi-layer structure 702 over the via such that the multi-layer structure includes a dielectric layer 604 sandwiched between a first metallic layer 602a and a second metallic layer 602b such that the first metallic layer 602a is electrically connected to the via 412, patterning the multi-layer structure 702 to thereby form a capacitor structure 402b including a dielectric element 403 sandwiched between a first conductor 405a and a second conductor 405b, such the first conductor 405a is electrically connected to the via 412, and electrically connecting the second conductor 405b to a ground line or to the source line (e.g., line 154) to thereby form the capacitive element.

According to the method 1100, forming the multi-layer structure may further include depositing TiN and/or TaN to thereby form the first metallic layer 602a and the second metallic layer 602b; and depositing one or more of hafnium oxide, hafnium lanthanum oxide, hafnium silicon oxide, hafnium tantalum oxide, hafnium titanium oxide, hafnium zirconium oxide, zirconium oxide, titanium oxide, aluminum oxide, and hafnium dioxide-alumina to thereby form the dielectric layer 604.

According to the method 1100, forming the first oxide definition region 302 on the substrate 150 and forming the second oxide definition region 304 on the substrate 150 may further include configuring the first oxide definition region 302 and the second oxide definition region 304 as fin structures such that the write access transistor, the storage transistor, and the read access transistor are each formed as FinFET devices (e.g., see FIG. 8 and related description).

Referring to all drawings and according to various embodiments of the present disclosure, a memory cell 202 (e.g., see FIGS. 4A, 5A, 6A, and 8) is provided. The memory cell 202 may include a read bit line RBL and a read word line RWL; a write bit line WBL and a write word line WWW; a source line SL; and a write access transistor MW including first source electrode 110a, a first drain electrode 112a, and a first gate 116a, wherein the first gate 116a is electrically connected to the write word line WWL and the first source electrode 110a is electrically connected to the write bit line WBL.

The memory cell 202 may further include a storage transistor MS including a second source electrode 110b, a second drain electrode 112b, and a second gate 116b, wherein the second gate 116b is electrically connected to the first drain electrode 112a and the second source electrode 110b is electrically connected to the source line SL; a read access transistor MR including a third source electrode 110c, a third drain electrode 112c, and a third gate 116c, wherein the third source electrode 110c is electrically connected to the second drain electrode 112b, the third gate 116c is electrically connected to the read word line RWL and the third drain electrode 112c is electrically connected to the read bit line RBL; and a capacitive element 402 having a first terminal 402a and a second terminal 402c, wherein the first terminal 402a is electrically connected to the first drain electrode 112a and the second gate 116b (e.g., see FIGS. 4A, 4B, and 4C). The second terminal 402c may be electrically connected to a ground line (e.g., line 410) or to the source line SL.

The capacitive element 402 may include a high-k dielectric element 403 sandwiched between a first conductor 405a and a second conductor 405b. In some embodiments, the first conductor 405a and the second conductor 405b may include TiN and/or TaN. The high-k dielectric element 403 may include one or more of hafnium oxide, hafnium lanthanum oxide, hafnium silicon oxide, hafnium tantalum oxide, hafnium titanium oxide, hafnium zirconium oxide, zirconium oxide, titanium oxide, aluminum oxide, and hafnium dioxide-alumina. In further embodiments, the high-k dielectric element 403 may include a multilayer structure including two or more layers, respectively, of two or more of hafnium oxide, hafnium lanthanum oxide, hafnium silicon oxide, hafnium tantalum oxide, hafnium titanium oxide, hafnium zirconium oxide, zirconium oxide, titanium oxide, aluminum oxide, and hafnium dioxide-alumina. In other embodiments, capacitive element 402 may include an alternating multi-layer structure 702 including silicon oxide and silicon nitride.

The capacitive element 402 may be formed on a first oxide definition region 302 associated with the write access transistor MR (e.g., see FIGS. 4A to 4D) or formed on a second oxide definition region 304 associated with the storage transistor MS and the read access transistor MR (e.g., see FIGS. 6A and 6B). In other embodiments, the capacitive element 402 may be formed on a continuous polysilicon region 308 that forms the second gate 116b and electrically connects a first oxide definition region 302 associated with the write access transistor MR to a second oxide definition region 304 associated with the storage transistor MS and the read access transistor MR (e.g., see FIGS. 5A and 5B).

In further embodiments, a memory cell 202 (e.g., see FIGS. 4A, 5A, 6A, and 8) is provided that includes a first oxide definition region 302 formed on a substrate (102, 150); a second oxide definition region 304 formed on the substrate (102, 150); a first continuous polysilicon region 306 formed over the first oxide definition region 302; a second continuous polysilicon region 308 formed over the first oxide definition region 302 and the second oxide definition region 304; a third continuous polysilicon region 310 formed over the second oxide definition region 304; and a capacitive element 402 formed on one of the first oxide definition region 302, the second oxide definition region 304, or the second continuous polysilicon region 308.

A first portion 312 of the first continuous polysilicon region 306 may be configured to be overlapping with the first oxide definition region 302 to thereby form a first gate 116a of a write access transistor MW. A second portion 314 of the second continuous polysilicon region 308 may be configured to be overlapping with the second oxide definition region 304 to thereby form a gate 116b of a storage transistor MS, and a third portion 316 of the third continuous polysilicon region 310 may be configured to be overlapping with the second oxide definition region 304 to thereby form a third gate 116c of a read access transistor MR.

The memory cell 202 may further include a read bit line RBL and a read word line RWL; a write bit line WBL and a write word line WWW; a source line SL; a first contact 318a formed at a first end of the first oxide definition region 302 that is electrically coupled with a source electrode 110a of the write access transistor MW, such that the first contact 318a is electrically connected to the write bit line WBL such that the source electrode 110a of the write access transistor MW is electrically connected to the write bit line WBL; a second contact 318b formed at a first end of the first continuous polysilicon region 306 and electrically connected to the write word line WWL such that the first gate 116a is electrically connected to the write word line WWL; a third contact 318c formed at a first end of the second oxide definition region 304 that is electrically coupled with a source electrode 110b of the storage transistor MS, such that the third contact 318c is electrically connected to the source line SL such that the source electrode 110b of the storage transistor MS is connected to the source line SL; a fourth contact 318d formed at a first end of the third continuous polysilicon region 310 and electrically connected to the read word line RWL such that the gate 116c of the read access transistor MR is electrically connected to the read word line RWL; and a fifth contact 318e formed at a second end of the second oxide definition region 304 that is electrically coupled with a drain electrode 112c of the read access transistor MR, such that the fifth contact 318e is electrically connected to the read bit line RBL such that the drain electrode 112c of the read access transistor MR is electrically connected to the read bit line RBL.

The first oxide definition region 302 and the second continuous polysilicon region 308 may be configured such that a drain electrode 112a of the write access transistor MR is electrically connected to the second gate 116b (i.e., the gate of the storage transistor MS). Further, the second oxide definition region 304 may be configured such that a second drain electrode 112b of the storage transistor MS is electrically connected to a third source electrode 110c of the read access transistor MR. The first oxide definition region 302 and the second oxide definition region 304 may each have a common width while in other embodiments the first oxide definition region 302 and the second oxide definition region 304 may have different widths.

In further embodiments, the first oxide definition region 302 and the second oxide definition region 304 may each formed as fin structures such that the write access transistor MW, the storage transistor MS, and the read access transistor MR are formed as FinFET devices (e.g., see FIG. 8 and related description). The capacitive element 402 may include a high-k dielectric element 604 sandwiched between a first conductor 405a and a second conductor 405b.

The above-described embodiments provide advantages over typical three transistor memory cells by providing a capacitive element that may reduce leakage currents and may thereby reduce a memory refresh rate. The capacitive element may be provided without increasing an area occupied by the write access transistor, the storage transistor, and the read access transistor. The new memory cell may therefore be incorporated in existing three transistor memory arrays with only minor modification of array designs. Further, the memory cell may be formed in an FEOL process or in a BEOL process. In embodiments formed in a BEOL process, the memory cell may be incorporated with other BEOL circuit components such as TFT devices. As such, the disclosed memory cell may include materials that may be processed at low temperatures and thus, may not damage previously fabricated devices (e.g., FEOL and MEOL devices).

The foregoing outlines features of several embodiments so that those skilled in the art may better understand the aspects of this disclosure. Those skilled in the art should appreciate that they may readily use this disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of this disclosure.

What is claimed is:

1. A method of forming a memory cell, comprising:
forming a read bit line and a read word line;
forming a write bit line and a write word line;
forming a source line;
forming a write access transistor comprising a first source, a first drain, and a first gate;
electrically connecting the first gate to the write word line and electrically connecting the first source to the write bit line;
forming a storage transistor comprising a second source, a second drain, and a second gate;
electrically connecting the second gate to the first drain and electrically connecting the second source to the source line;
forming a read access transistor comprising a third source, a third drain, and a third gate;
electrically connecting the third source to the second drain, electrically connecting the third gate to the read word line, and electrically connecting the third drain to the read bit line;
forming a capacitive element having a first terminal and a second terminal;
electrically connecting the first terminal is electrically connected to the first drain and the second gate.

2. The method of claim 1, further comprising forming a first contact at a first end of a first oxide definition region to thereby form the first source of the write access transistor.

3. The method of claim 1, further comprising:
forming a second contact at a first end of a first continuous polysilicon region;
electrically connecting the second contact to the write word line such that the first gate is electrically connected to the write word line.

4. The method of claim 1, further comprising forming a third contact at a first end of a second oxide definition region to thereby form a second source of the storage transistor.

5. The method of claim 1, further comprising:
forming a fourth contact at a first end of a third continuous polysilicon region; and
electrically connecting the fourth contact to the read word line such that the third gate is electrically connected to the read word line.

6. The method of claim 1, further comprising forming a fifth contact at a second end of a second oxide definition region to thereby form a third drain of the read access transistor.

7. The method of claim 1, wherein a first oxide definition region and a second continuous polysilicon region are configured such that the first drain of the write access transistor is electrically connected to the second gate.

8. The method of claim 1, wherein a second oxide definition region is configured such that the second drain of the storage transistor is electrically connected to the third source of the read access transistor.

9. The method of claim 1, further comprising electrically connecting the second terminal to a ground line.

10. The method of claim 1, further comprising electrically connecting the second terminal to a voltage line held at VDD.

11. The method of claim 1, wherein forming the capacitive element further comprises:
forming an interlayer dielectric layer over a first oxide definition region;
etching the interlayer dielectric layer to thereby form a via cavity, wherein the etching is allowed to progress until a surface of the first oxide definition region is exposed;
forming an electrically conducting via in the via cavity such that the electrically conducting via makes electrical contact with the surface of the first oxide definition region;
forming a multi-layer structure over the via, wherein the multi-layer structure comprises a dielectric layer sandwiched between a first metallic layer and a second metallic layer such that the first metallic layer is electrically connected to the via;
patterning the multi-layer structure to thereby form a capacitor structure comprising a dielectric element sandwiched between a first conductor and a second conductor, wherein the first conductor is electrically connected to the via; and
electrically connecting the second conductor to a ground line or to the source line to thereby form the capacitive element.

12. The method of claim 11, wherein forming the multi-layer structure further comprises:
depositing one or more of TiN and TaN to thereby form the first metallic layer and the second metallic layer; and
depositing one or more of hafnium oxide, hafnium lanthanum oxide, hafnium silicon oxide, hafnium tantalum oxide, hafnium titanium oxide, hafnium zirconium oxide, zirconium oxide, titanium oxide, aluminum oxide, and hafnium dioxide-alumina to thereby form the dielectric layer.

13. The method of claim 12, wherein forming the first oxide definition region on the substrate comprises configuring the first oxide definition region as a fin structure such that the write access transistor, the storage transistor, and the read access transistor are each formed as FinFET devices.

14. A method of fabricating a memory cell, comprising:
forming a first continuous polysilicon region over the first oxide definition region;
forming a second continuous polysilicon region over and electrically connected to the first oxide definition region, and overlapping a second oxide definition region;
forming a third continuous polysilicon region over the second oxide definition region; and
forming an interlayer dielectric layer over the first oxide definition region;
etching the interlayer dielectric layer to thereby form a via cavity, wherein the etching is allowed to progress until a surface of the first oxide definition region is exposed;
forming an electrically conducting via in the via cavity such that the electrically conducting via makes electrical contact with the surface of the first oxide definition region;
forming a multi-layer structure over the via, wherein the multi-layer structure comprises a dielectric layer sandwiched between a first metallic layer and a second metallic layer such that the first metallic layer is electrically connected to the via;
patterning the multi-layer structure to thereby form a capacitor structure comprising a dielectric element sandwiched between a first conductor and a second conductor, wherein the first conductor is electrically connected to the via; and
electrically connecting the second conductor to a ground line or to the source line to thereby form the capacitive element.

15. The method of claim 14, wherein forming the multi-layer structure further comprises:
depositing one or more of TiN and TaN to thereby form the first metallic layer and the second metallic layer; and
depositing one or more of hafnium oxide, hafnium lanthanum oxide, hafnium silicon oxide, hafnium tantalum oxide, hafnium titanium oxide, hafnium zirconium oxide, zirconium oxide, titanium oxide, aluminum oxide, and hafnium dioxide-alumina to thereby form the dielectric layer.

16. The method of claim 15, wherein forming the first oxide definition region on the substrate and forming the second oxide definition region on the substrate comprises configuring the first oxide definition region and the second oxide definition region as fin structures such that the write access transistor, the storage transistor, and the read access transistor are each formed as FinFET devices.

17. A method of fabricating a memory cell, comprising:
forming a first oxide definition region on a substrate;
forming a second oxide definition region on the substrate;
forming a first continuous polysilicon region over the first oxide definition region;
forming a second continuous polysilicon region over and electrically connected to the first oxide definition region, and overlapping the second oxide definition region;
forming a third continuous polysilicon region over the second oxide definition region;
forming a capacitive element on one of the first oxide definition region, on the second oxide definition region, or the second continuous polysilicon region;
forming a first contact at a first end of the first oxide definition region to thereby form a first source of a write access transistor;
electrically connecting the first contact to a write bit line such that the first source is electrically connected to the write bit line;
forming a second contact at a first end of the first continuous polysilicon region;
electrically connecting the second contact to a write word line such that the first gate is electrically connected to the write word line;
forming a third contact at a first end of the second oxide definition region to thereby form a second source of a storage transistor;
electrically connecting the third contact to a source line such that the second source is connected to the source line;
forming a fourth contact at a first end of the third continuous polysilicon region;
electrically connecting the fourth contact to a read word line such that the third gate is electrically connected to the read word line;
forming a fifth contact at a second end of the second oxide definition region to thereby form a third drain of a read access transistor; and
electrically connecting the fifth contact to a read bit line such that the third drain is electrically connected to the read bit line.

18. The method of claim 17, wherein forming the capacitive element further comprises:
forming an interlayer dielectric layer over the first oxide definition region;
etching the interlayer dielectric layer to thereby form a via cavity, wherein the etching is allowed to progress until a surface of the first oxide definition region is exposed;
forming an electrically conducting via in the via cavity such that the electrically conducting via makes electrical contact with the surface of the first oxide definition region;
forming a multi-layer structure over the via, wherein the multi-layer structure comprises a dielectric layer sandwiched between a first metallic layer and a second metallic layer such that the first metallic layer is electrically connected to the via;
patterning the multi-layer structure to thereby form a capacitor structure comprising a dielectric element sandwiched between a first conductor and a second conductor, wherein the first conductor is electrically connected to the via; and
electrically connecting the second conductor to a ground line or to the source line to thereby form the capacitive element.

19. The method of claim 18, wherein forming the multi-layer structure further comprises:
depositing one or more of TiN and TaN to thereby form the first metallic layer and the second metallic layer; and
depositing one or more of hafnium oxide, hafnium lanthanum oxide, hafnium silicon oxide, hafnium tantalum oxide, hafnium titanium oxide, hafnium zirconium oxide, zirconium oxide, titanium oxide, aluminum oxide, and hafnium dioxide-alumina to thereby form the dielectric layer.

20. The method of claim 17, wherein forming the first oxide definition region on the substrate and forming the second oxide definition region on the substrate comprises configuring the first oxide definition region and the second oxide definition region as fin structures such that the write access transistor, the storage transistor, and the read access transistor are each formed as FinFET devices.
